(19) United States
(12) Patent Application Publication
(10) Pub. No.: US 2026/0164961 A1
(43) Pub. Date: Jun. 11, 2026

(54) ARRAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Tiaomei Zhang, Beijing (CN); Wenhui Gao, Beijing (CN); Zhiliang Jiang, Beijing (CN); Jianpeng Wu, Beijing (CN); Ming Hu, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/729,121

(22) PCT Filed: Sep. 26, 2023
(86) PCT No.: PCT/CN2023/121348

§ 371 Date: Jul. 15, 2024

(51) Int. Cl. H10K 59/131; H10D 86/40; H10D 86/60; H10K 59/121

(52) U.S. Cl. CPC H10K 59/131; H10K 59/1213; H10K 59/1216; H10D 86/441; H10D 86/481; H10D 86/60

(57) ABSTRACT

An array substrate. The array substrate includes a plurality of pixel driving circuits; wherein a respective pixel driving circuit (PDC) of the plurality of pixel driving circuits comprises a driving transistor (Td), a first light emitting control transistor (T3), and a third reset transistor (Tr3); active layers (ACTd,ACT3,ACTr3) of the driving transistor (Td), the first light emitting control transistor (T3), and the third reset transistor (Tr3) are in a first semiconductor material layer (SML1); a first electrode (Sd) of the driving transistor (Td), a second electrode (D3) of the first light emitting control transistor (T3), and a second electrode (Dr3) of the third reset transistor (Tr3) are in the first semiconductor material layer (SML1); the first electrode (Sd) of the driving transistor (Td), the second electrode (D3) of the first light emitting control transistor (T3), and the second electrode (Dr3) of the third reset transistor (Tr3) are parts of a unitary structure; and the first electrode (Sd) of the driving transistor (Td), the second electrode (D3) of the first light emitting control transistor (T3), and the second electrode (Dr3) of the third reset transistor (Tr3) are connected to each other by one or more portions of the first semiconductor material layer (SML1).

### TECHNICAL FIELD

The present invention relates to display technology, more particularly, to an array substrate and a display apparatus.

### BACKGROUND

Organic Light Emitting Diode (OLED) display is one of the hotspots in the field of flat panel display research today. OLED is driven by a driving current required to be kept constant to control illumination. The OLED display panel includes a plurality of pixel units configured with pixel-driving circuits arranged in multiple rows and columns.

### SUMMARY

In a first aspect, the present disclosure provides an array substrate, comprising a plurality of pixel driving circuits; wherein a respective pixel driving circuit of the plurality of pixel driving circuits comprises a driving transistor, a first light emitting control transistor, and a third reset transistor; active layers of the driving transistor, the first light emitting control transistor, and the third reset transistor are in a first semiconductor material layer; a first electrode of the driving transistor, a second electrode of the first light emitting control transistor, and a second electrode of the third reset transistor are in the first semiconductor material layer; the first electrode of the driving transistor, the second electrode of the first light emitting control transistor, and the second electrode of the third reset transistor are parts of a unitary structure; and the first electrode of the driving transistor, the second electrode of the first light emitting control transistor, and the second electrode of the third reset transistor are connected to each other by one or more portions of the first semiconductor material layer.

In some embodiments according to the present disclosure, the array substrate further comprises: a first light emitting control electrode pad on the first semiconductor material layer; and a plurality of light emitting control signal lines on a side of the first light emitting control electrode pad away from the first semiconductor material layer; wherein the first light emitting control electrode pad comprises a gate electrode of the first light emitting control transistor; and a respective light emitting control signal line of the plurality of light emitting control signal lines is connected to the first light emitting control electrode pad through a via.

In some embodiments according to the present disclosure, the array substrate further comprises: a second light emitting control electrode pad on the first semiconductor material layer; and a plurality of light emitting control signal lines on a side of the second light emitting control electrode pad away from the first semiconductor material layer; wherein the respective pixel driving circuit further comprises a second light emitting control transistor; the second light emitting control electrode pad comprises a gate electrode of the second light emitting control transistor; and a respective light emitting control signal line of the plurality of light emitting control signal lines is connected to the second light emitting control electrode pad through a via.

In some embodiments according to the present disclosure, the respective pixel driving circuit further comprises a storage capacitor comprising a first capacitor electrode and a second capacitor electrode; the first light emitting control electrode pad and the first capacitor electrode are in a first gate metal layer; the second capacitor electrode is in a second gate metal layer on a side of the first gate metal layer away from the first semiconductor material layer; the plurality of light emitting control signal lines are in a first signal line layer on a side of the second gate metal layer away from the first gate metal layer.

In some embodiments according to the present disclosure, the respective pixel driving circuit further comprises a compensating transistor; an active layer of the compensating transistor is in a second semiconductor material layer on a side of the second gate metal layer away from the first gate metal layer; at least a portion of a gate electrode of the compensating transistor is in a third gate metal layer on a side of the second semiconductor material layer away from the second gate metal layer; and the plurality of light emitting control signal lines are in the first signal line layer on a side of the third gate metal layer away from the second semiconductor material layer.

In some embodiments according to the present disclosure, the array substrate further comprises: a first voltage connecting pad and a plurality of first voltage supply lines; wherein an active layer of the first light emitting control transistor, the first voltage connecting pad, and the plurality of first voltage supply lines are in three different layers; and a respective first voltage supply line of the plurality of first voltage supply lines is connected to the first voltage connecting pad, and the first voltage connecting pad is connected to a first electrode of the first light emitting control transistor.

In some embodiments according to the present disclosure, an orthographic projection of the second electrode of the third reset transistor on a base substrate at least partially overlaps with an orthographic projection of the first voltage connecting pad on the base substrate.

In some embodiments according to the present disclosure, the array substrate further comprises: a plurality of light emitting control signal lines; wherein a respective light emitting control signal line of the plurality of light emitting control signal lines is configured provide a light emitting control signal to a gate electrode of the first light emitting control transistor; and the first voltage connecting pad is in a same layer as the plurality of light emitting control signal lines.

In some embodiments according to the present disclosure, the first voltage connecting pad is connected to first electrodes of first light emitting control transistors in two adjacent pixel driving circuits in a same row.

In some embodiments according to the present disclosure, the respective first voltage supply line comprises a main body and a plurality of extensions extending away from the main body; a respective extension of the plurality of extensions is connected to the first voltage connecting pad; and the first voltage connecting pad is connected to the first electrode of the first light emitting control transistor.

In some embodiments according to the present disclosure, the respective pixel driving circuit further comprises a compensating transistor; an active layer of the compensating transistor is in a second semiconductor material layer on a side of the first semiconductor material layer away from a base substrate; an orthographic projection of the main body on the base substrate substantially covers an orthographic projection of the active layer of the compensating transistor on the base substrate.

In some embodiments according to the present disclosure, the orthographic projection of the main body on the base substrate substantially covers an orthographic projection of a first electrode, the active layer, and a second electrode of the compensating transistor on the base substrate.

In some embodiments according to the present disclosure, the respective pixel driving circuit further comprises a first reset transistor and a second reset transistor; wherein the array substrate further comprises: a plurality of third reset signal lines configured to provide a third reset signal to first electrodes of third reset transistors in the plurality of pixel driving circuits; and a plurality of first reset signal lines configured to provide a first reset signal to first electrodes of first reset transistors in the plurality of pixel driving circuits, and/or a plurality of second reset signal lines configured to provide a second reset signal to first electrodes of second reset transistors in the plurality of pixel driving circuits; wherein the plurality of first reset signal lines, the plurality of second reset signal lines, and the plurality of third reset signal lines extend along a direction substantially parallel to a first direction.

In some embodiments according to the present disclosure, the array substrate further comprises: a plurality of third reset signal lines configured to provide a third reset signal to first electrodes of third reset transistors in the plurality of pixel driving circuits; a plurality of first low voltage supply lines; a plurality of fourth reset signal lines; a plurality of fifth reset signal lines; a plurality of sixth reset signal lines; and a plurality of second low voltage supply lines; wherein the plurality of third reset signal lines and the plurality of first low voltage signal lines extend along a direction substantially parallel to a first direction; the plurality of fourth reset signal lines, the plurality of fifth reset signal lines, the plurality of sixth reset signal lines, and the plurality of second low voltage supply lines extend along a direction substantially parallel to a second direction; the second direction is different from the first direction; and the plurality of fourth reset signal lines, the plurality of fifth reset signal lines, the plurality of sixth reset signal lines, and the plurality of second low voltage supply lines are in a same layer on a side of the plurality of third reset signal lines and the plurality of first low voltage signal lines away from the first semiconductor material layer.

In some embodiments according to the present disclosure, the plurality of fourth reset signal lines, the plurality of fifth reset signal lines, the plurality of sixth reset signal lines, and the plurality of second low voltage supply lines are alternately arranged.

In some embodiments according to the present disclosure, the plurality of pixel driving circuits are arranged in J number of columns, J being a positive integer; the J number of columns comprise a (8j-7)-th column of the J columns, a (8j-6)-th column of the J columns, a (8j-5)-th column of the J columns, a (8j-4)-th column of the J columns, a (8j-3)-th column of the J columns, a (8j-2)-th column of the J columns, a (8j-1)-th column of the J columns, and a (8j)-th column of J columns, j being a positive integer, 1≤j≤(J/8); one of a respective fourth reset signal line of the plurality of fourth reset signal lines, a respective fifth reset signal line of the plurality of fifth reset signal lines, a respective sixth reset signal line of the plurality of sixth reset signal lines, and a respective second low voltage supply line of the plurality of second low voltage supply lines is between the (8j-7)-th column and the (8j-6)-th column; another of the respective fourth reset signal line, the respective fifth reset signal line, the respective sixth reset signal line, and the respective second low voltage supply line is between the (8j-5)-th column and the (8j-4)-th column; another of the respective fourth reset signal line, the respective fifth reset signal line, the respective sixth reset signal line, and the respective second low voltage supply line is between the (8j-3)-th column and the (8j-2)-th column; and another of the respective fourth reset signal line, the respective fifth reset signal line, the respective sixth reset signal line, and the respective second low voltage supply line is between the (8j-1)-th column and the (8j)-th column.

In some embodiments according to the present disclosure, the array substrate further comprises: a first respective anode, a second respective anode, a third respective anode, and a fourth respective anode; wherein the first respective anode is an anode for a subpixel of a first color, the second respective anode is an anode for a subpixel of a second color, the third respective anode and the fourth respective anode are anodes for two subpixels of a third color; an orthographic projection of the third respective anode on the base substrate at least partially overlaps with an orthographic projection of two adjacent second voltage supply lines of the plurality of second voltage supply lines on the base substrate, and at least partially overlaps with an orthographic projection of one of a respective fourth reset signal line, a respective fifth reset signal line, a respective sixth reset signal line, and a respective second low voltage supply line on the base substrate; and an orthographic projection of the fourth respective anode on the base substrate at least partially overlaps with an orthographic projection of two adjacent second voltage supply lines of the plurality of second voltage supply lines on the base substrate, and at least partially overlaps with an orthographic projection of one of a respective fourth reset signal line, a respective fifth reset signal line, a respective sixth reset signal line, and a respective second low voltage supply line on the base substrate.

In some embodiments according to the present disclosure, an orthographic projection of at least one of the first respective anode, the second respective anode, the third respective anode, or the fourth respective anode on the base substrate at least partially overlaps with an orthographic projection of the second electrode of the third reset transistor on the base substrate.

In a second aspect, the present disclosure provides an array substrate, comprising a plurality of pixel driving circuits: wherein a respective pixel driving circuit of the plurality of pixel driving circuits comprises a second node connecting line, a first light emitting control transistor, a third reset transistor, and a second node connecting line; the second node connecting line is connected to a second electrode of the first light emitting control transistor, and connected to a second electrode of the third reset transistor; and the second node connecting line is in a same layer as active layers of the first light emitting control transistor and the third reset transistor.

In some embodiments according to the present disclosure, the array substrate further comprises: a plurality of light emitting control signal lines; wherein a respective light emitting control signal line of the plurality of light emitting control signal lines is configured to provide a control signal to a gate electrode of the first light emitting control transistor; and the plurality of light emitting control signal lines are spaced apart from the second node connecting line by at least three insulating layers.

In some embodiments according to the present disclosure, the respective pixel driving circuit further comprises a first node connecting line, a storage capacitor, and a compensating transistor; the first node connecting line is connected to a first capacitor electrode of the storage capacitor, and is connected to a first electrode of the compensating transistor; and the plurality of light emitting control signal lines and the first node connecting line are in a same layer.

In a third aspect, the present disclosure provides a display apparatus, comprising the above array substrate, and one or more integrated circuits connected to the array substrate.

### BRIEF DESCRIPTION OF THE FIGURES

The following drawings are merely examples for illustrative purposes according to various disclosed embodiments and are not intended to limit the scope of the present invention.

FIG. 1 is a plan view of an array substrate in some embodiments according to the present disclosure.

FIG. 2A is a circuit diagram illustrating the structure of a pixel driving circuit in some embodiments according to the present disclosure.

FIG. 2B is a timing diagram illustrating the operation of a pixel driving circuit in some embodiments according to the present disclosure.

FIG. 3A is a diagram illustrating the structure of pixel driving circuits in an array substrate in some embodiments according to the present disclosure.

FIG. 3B is a diagram illustrating the structure of a first semiconductor material layer, a first gate metal layer, a second gate metal layer, a second semiconductor material layer, a third gate metal layer, and a first signal line layer in the array substrate depicted in FIG. 3A.

FIG. 3C is a schematic diagram illustrating an arrangement of pixel driving circuits in the array substrate depicted in FIG. 3A.

FIG. 3D is a diagram illustrating the structure of a first semiconductor material layer in the array substrate depicted in FIG. 3A.

FIG. 3E is a diagram illustrating the structure of a first gate metal layer in the array substrate depicted in FIG. 3A.

FIG. 3F is a diagram illustrating the structure of a second gate metal layer in the array substrate depicted in FIG. 3A.

FIG. 3G is a diagram illustrating the structure of a second semiconductor material layer in the array substrate depicted in FIG. 3A.

FIG. 3H is a diagram illustrating the structure of a third gate metal layer in the array substrate depicted in FIG. 3A.

FIG. 3I is a diagram illustrating the structure of a passivation layer in the array substrate depicted in FIG. 3A.

FIG. 3J is a diagram illustrating the structure of a first signal line layer in the array substrate depicted in FIG. 3A.

FIG. 3K is a diagram illustrating the structure of a first planarization layer in the array substrate depicted in FIG. 3A.

FIG. 3L is a diagram illustrating the structure of a second signal line layer in the array substrate depicted in FIG. 3A.

FIG. 3M is a diagram illustrating the structure of a second planarization layer in the array substrate depicted in FIG. 3A.

FIG. 3N is a diagram illustrating the structure of a third signal line layer in the array substrate depicted in FIG. 3A.

FIG. 3O is a diagram illustrating the structure of an anode layer in the array substrate depicted in FIG. 3A.

FIG. 4A is a cross-sectional view along an A-A′ line in FIG. 3A.

FIG. 4B is a cross-sectional view along a B-B′ line in FIG. 3A.

FIG. 5 illustrates a voltage supply path in an array substrate in some embodiments according to the present disclosure.

FIG. 6 is a diagram illustrating the structure of a respective first voltage supply line in an array substrate in some embodiments according to the present disclosure.

FIG. 7 is a diagram illustrating the structure of a second semiconductor material layer and a respective first voltage supply line in the array substrate depicted in FIG. 3A.

FIG. 8A is a diagram illustrating the structure of pixel driving circuits in an array substrate in some embodiments according to the present disclosure.

FIG. 8B is a schematic diagram illustrating an arrangement of pixel driving circuits in the array substrate depicted in FIG. 8A.

FIG. 8C is a diagram illustrating the structure of a first semiconductor material layer in the array substrate depicted in FIG. 8A.

FIG. 8D is a diagram illustrating the structure of a first gate metal layer in the array substrate depicted in FIG. 8A.

FIG. 8E is a diagram illustrating the structure of a second gate metal layer in the array substrate depicted in FIG. 8A.

FIG. 8F is a diagram illustrating the structure of a second semiconductor material layer in the array substrate depicted in FIG. 8A.

FIG. 8G is a diagram illustrating the structure of a third gate metal layer in the array substrate depicted in FIG. 8A.

FIG. 8H is a diagram illustrating the structure of a passivation layer in the array substrate depicted in FIG. 8A.

FIG. 8I is a diagram illustrating the structure of a first signal line layer in the array substrate depicted in FIG. 8A.

FIG. 8J is a diagram illustrating the structure of a first planarization layer in the array substrate depicted in FIG. 8A.

FIG. 8K is a diagram illustrating the structure of a second signal line layer in the array substrate depicted in FIG. 8A.

FIG. 8L is a diagram illustrating the structure of a second planarization layer in the array substrate depicted in FIG. 8A.

FIG. 8M is a diagram illustrating the structure of a third signal line layer in the array substrate depicted in FIG. 8A.

FIG. 8N is a diagram illustrating the structure of an anode layer in the array substrate depicted in FIG. 8A.

FIG. 8O is a diagram illustrating the structure of a third signal line layer and an anode layer in the array substrate depicted in FIG. 8A.

FIG. 8P is a diagram illustrating the structure of a first semiconductor material layer and an anode layer in the array substrate depicted in FIG. 8A.

FIG. 9A illustrates a first interconnected reset signal network in some embodiments according to the present disclosure.

FIG. 9B illustrates a first interconnected reset signal network in some embodiments according to the present disclosure.

FIG. 10A illustrates a second interconnected reset signal network in some embodiments according to the present disclosure.

FIG. 10B illustrates a second interconnected reset signal network in some embodiments according to the present disclosure.

FIG. 11 illustrates a third interconnected reset signal network in some embodiments according to the present disclosure.

FIG. 12 illustrates an interconnected low voltage supply network in some embodiments according to the present disclosure.

FIG. 13 is a diagram illustrating the structure of a first semiconductor material layer in the array substrate depicted in FIG. 3A.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, an array substrate and a display apparatus that substantially obviate one or more of the problems due to limitations and disadvantages of the related art. In one aspect, the present disclosure provides an array substrate. In some embodiments, the array substrate includes a plurality of pixel driving circuits. Optionally, a respective pixel driving circuit of the plurality of pixel driving circuits comprises a driving transistor, a data write transistor, a first light emitting control transistor, and a third reset transistor. Optionally, active layers of the driving transistor, the data write transistor, the first light emitting control transistor, and the third reset transistor are in a first semiconductor material layer. Optionally, a second electrode of the data write transistor, a first electrode of the driving transistor, a second electrode of the first light emitting control transistor, and a second electrode of the third reset transistor are in first semiconductor material layer. Optionally, the second electrode of the data write transistor, the first electrode of the driving transistor, the second electrode of the first light emitting control transistor, and the second electrode of the third reset transistor are parts of a unitary structure. Optionally, the second electrode of the data write transistor, the first electrode of the driving transistor, the second electrode of the first light emitting control transistor, and the second electrode of the third reset transistor are connected to each other by one or more portions of the first semiconductor material layer.

Various appropriate pixel driving circuits may be used in the present array substrate. Examples of appropriate driving circuits include 3T1C, 2T1C, 4T1C, 4T2C, 5T2C, 6T1C, 7T1C, 7T2C, 8T1C, and 8T2C. In some embodiments, the respective one of the plurality of pixel driving circuits is an 8T1C driving circuit. Various appropriate light emitting elements may be used in the present array substrate. Examples of appropriate light emitting elements include organic light emitting diodes, quantum dots light emitting diodes, and micro light emitting diodes. Optionally, the light emitting element is micro light emitting diode. Optionally, the light emitting element is an organic light emitting diode including an organic light emitting layer.

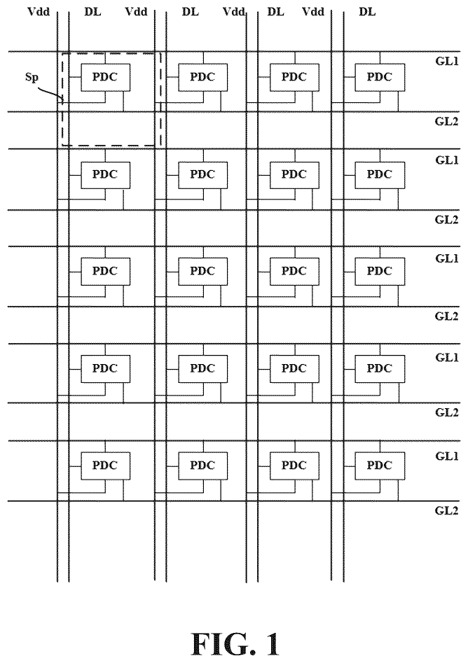

FIG. 1 is a plan view of an array substrate in some embodiments according to the present disclosure. Referring to FIG. 1, the array substrate includes an array of subpixels Sp. Each subpixel includes an electronic component, e.g., a light emitting element. In one example, the light emitting element is driven by a respective pixel driving circuit PDC. The array substrate includes a plurality of first gate lines (e.g., a respective first gate line GL1), a plurality of second gate lines (e.g., a respective second gate line GL2), a plurality of data lines (e.g., a respective data line DL), a plurality of high voltage supply lines (e.g., a respective high voltage supply line Vdd), and a plurality of low voltage supply lines (e.g., a respective low voltage supply line Vss). Light emission in a respective subpixel Sp is driven by a respective pixel driving circuit PDC. In one example, a high voltage signal (e.g., a VDD signal) is input, through the respective high voltage supply line Vdd of the plurality of high voltage supply line, to the respective pixel driving circuit PDC connected to an anode of the light emitting element; a low voltage signal (e.g., a VSS signal) is input, through a low voltage supply line, to a cathode of the light emitting element. A voltage difference between the high voltage signal (e.g., the VDD signal) and the low voltage signal (e.g., the VSS signal) is a driving voltage AV that drives light emission in the light emitting element.

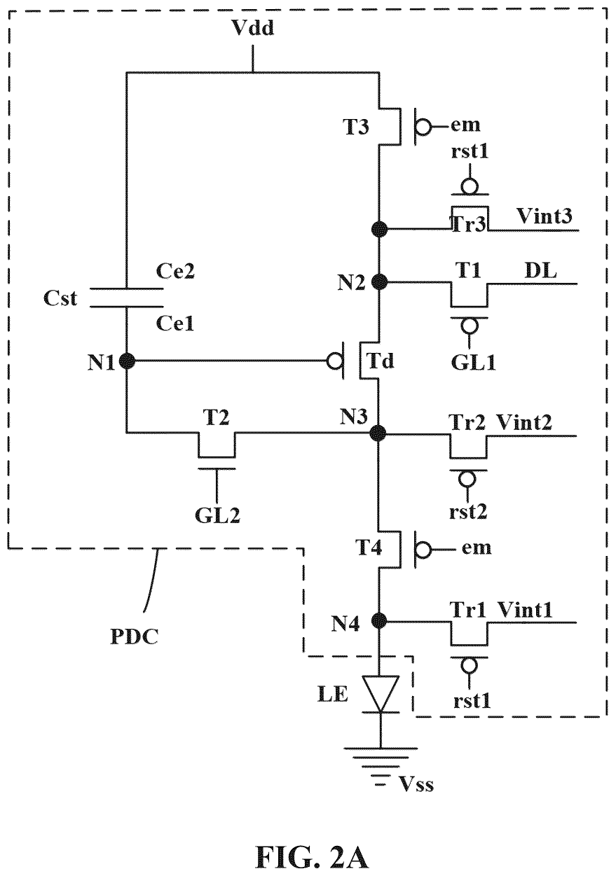

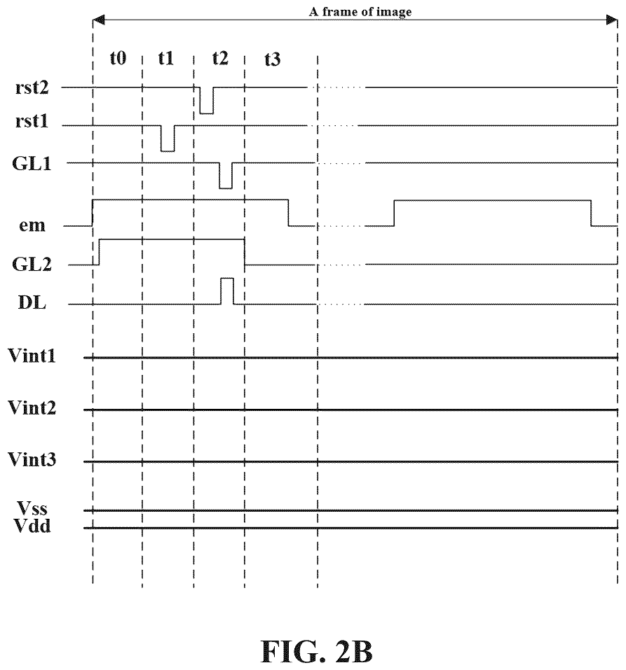

FIG. 2A is a circuit diagram illustrating the structure of a pixel driving circuit in some embodiments according to the present disclosure. Referring to FIG. 2A, in some embodiments, the pixel driving circuit includes a driving transistor Td; a storage capacitor Cst having a first capacitor electrode Cel and a second capacitor electrode Ce2; a second reset transistor Tr2 having a gate electrode connected to a respective second reset control signal line rst2 of a plurality of second reset control signal lines, a first electrode connected to a respective second reset signal line Vint2 of a plurality of second reset signal lines, and a second electrode connected to a second electrode of the driving transistor Td; a first transistor T1 having a gate electrode connected to a respective first gate line GL1 of a plurality of first gate lines, a first electrode connected to a respective data line DL of a plurality of data lines, and a second electrode connected to a first electrode of the driving transistor Td; a third reset transistor Tr3 having a gate electrode connected to a respective first reset control signal line rst1 of a plurality of first reset control signal lines, a first electrode connected to a respective third reset signal line Vint3 of a plurality of third reset signal lines, and a second electrode connected to the first electrode of the driving transistor Td; a second transistor T2 having a gate electrode connected to a respective second gate line GL2 of a plurality of second gate lines, a first electrode connected to the first capacitor electrode Cel of the storage capacitor Cst and the gate electrode of the driving transistor Td, and a second electrode connected to the second electrode of the driving transistor Td; a third transistor T3 having a gate electrode connected to a respective light emitting control signal line em of a plurality of light emitting control signal lines, a first electrode connected to a respective voltage supply line Vdd of a plurality of voltage supply lines, and a second electrode connected to the first electrode of the driving transistor Td and the second electrode of the first transistor T1; a fourth transistor T4 having a gate electrode connected to the respective light emitting control signal line em of the plurality of light emitting control signal lines, a first electrode connected to second electrodes of the driving transistor Td and the second transistor T2, and a second electrode connected to an anode of a light emitting element LE; and a first reset transistor Trl having a gate electrode connected to the respective first reset control signal line rst1 of a plurality of first reset control signal lines, a first electrode connected to a respective first reset signal line Vint1 of a plurality of first reset signal lines, and a second electrode connected to the second electrode of the fourth transistor T4 and the anode of the light emitting element LE. The second capacitor electrode Ce2 is connected to the respective voltage supply line and the first electrode of the third transistor T3.

In some embodiments, the pixel driving circuit includes a driving transistor Td, a data write transistor (e.g., the first transistor T1), a compensating transistor (e.g., the second transistor T2), two light emitting control transistors (e.g., the third transistor T3 and the fourth transistor T4), and three reset transistors (e.g., the first reset transistor Tr1, the second reset transistor Tr2, and the third reset transistor Tr3).

As used herein, a first electrode or a second electrode refers to one of a first terminal and a second terminal of a transistor, the first terminal and the second terminal being connected to an active layer of the transistor. A direction of a current flowing through the transistor may be configured to be from a first electrode to a second electrode, or from a second electrode to a first electrode. Accordingly, depending on the direction of the current flowing through the transistor, in one example, the first electrode is configured to receive an input signal and the second electrode is configured to output an output signal; in another example, the second electrode is configured to receive an input signal and the first electrode is configured to output an output signal.

The pixel driving circuit further include a first node N1, a second node N2, a third node N3, and a fourth node N4. The first node N1 is connected to the gate electrode of the driving transistor Td, the first capacitor electrode Ce1, and the first electrode of the second transistor T2. The second node N2 is connected to the second electrode of the third transistor T3, the second electrode of the first transistor T1, the second electrode of the third reset transistor Tr3, and the first electrode of the driving transistor Td. The third node N3 is connected to the second electrode of the driving transistor Td, the second electrode of the second transistor T2, the first electrode of the fourth transistor T4, and the second electrode of the second reset transistor Tr2. The fourth node N4 is connected to the second electrode of the fourth transistor T4, the second electrode of the first reset transistor Tr1, and the anode of the light emitting element LE.

The array substrate in some embodiments includes a plurality of subpixels. In some embodiments, the plurality of subpixels include a respective first subpixel, a respective second subpixel, and a respective third subpixel. Optionally, a respective pixel of the array substrate includes the respective first subpixel, the respective second subpixel, and the respective third subpixel. The plurality of subpixels in the array substrate are arranged in an array. In one example, the array of the plurality of subpixels includes a S1-S2-S3 format repeating array, in which S1 stands for the respective first subpixel, S2 stands for the respective second subpixel, and S3 stands for the respective third subpixel. In another example, the S1-S2-S3 format is a C1-C2-C3 format, in which C1 stands for the respective first subpixel of a first color, C2 stands for the respective second subpixel of a second color, and C3 stands for the respective third subpixel of a third color. In another example, the C1-C2-C3 format is an R-G-B format, in which the respective first subpixel is a red subpixel, the respective second subpixel is a green subpixel, and the respective third subpixel is a blue subpixel.

In another example, the array of the plurality of subpixels includes a S1-S2-S3-S4 format repeating array, in which S1 stands for the respective first subpixel, S2 stands for the respective second subpixel, S3 stands for the respective third subpixel, and S4 stands for the respective fourth subpixel. In another example, the S1-S2-S3-S4 format is a C1-C2-C3-C4 format, in which C1 stands for the respective first subpixel of a first color, C2 stands for the respective second subpixel of a second color, C3 stands for the respective third subpixel of a third color, and C4 stands for the respective fourth subpixel of a fourth color. In another example, the S1-S2-S3-S4 format is a C1-C2-C3-C2′ format, in which C1 stands for the respective first subpixel of a first color, C2 stands for the respective second subpixel of a second color, C3 stands for the respective third subpixel of a third color, and C2′ stands for the respective fourth subpixel of the second color. In another example, the C1-C2-C3-C2′ format is a R-G-B-G format, in which the respective first subpixel is a red subpixel, the respective second subpixel is a green subpixel, the respective third subpixel is a blue subpixel, and the respective fourth subpixel is a green subpixel.

In some embodiments, a minimum repeating unit of the plurality of subpixels of the array substrate includes the respective first subpixel, the respective second subpixel, and the respective third subpixel. Optionally, each of the respective first subpixel, the respective second subpixel, and the respective third subpixel, includes the first transistor T1, the second transistor T2, the third transistor T3, the fourth transistor T4, the first reset transistor Tr1, the second reset transistor Tr2, the third reset transistor Tr3, the driving transistor Td, and the storage capacitor Cst.

In alternative embodiments, a minimum repeating unit of the plurality of subpixels of the array substrate includes a respective first subpixel, a respective second subpixel, a respective third subpixel, and a respective fourth subpixel. Optionally, each of the respective first subpixel, the respective second subpixel, the respective third subpixel, and the respective fourth subpixel, includes the first transistor T1, the second transistor T2, the third transistor T3, the fourth transistor T4, the first reset transistor Tr1, the second reset transistor Tr2, the third reset transistor Tr3, the driving transistor Td, and the storage capacitor Cst.

The present disclosure may be implemented in pixel driving circuit having transistors of various types, including a pixel driving circuit having p-type transistors, a pixel driving circuit having n-type transistors, and a pixel driving circuit having one or more p-type transistors and one or more n-type transistors. Referring to FIG. 2A, the second transistor T2 is an n-type transistor such as a metal oxide transistor, and other transistors are p-type transistors such as polysilicon transistors. For a p-type transistor, an effective control signal (e.g., a turn-on control signal) is a low voltage signal, and an ineffective control signal (e.g., a turn-off control signal) is a high voltage signal. For an n-type transistor, an effective control signal (e.g., a turn-on control signal) is a high voltage signal, and an ineffective control signal (e.g., a turn-off control signal) is a low voltage signal.

FIG. 2B is a timing diagram illustrating the operation of a pixel driving circuit in some embodiments according to the present disclosure. Referring to FIG. 2A and FIG. 2B, during one frame of image, the operation of the pixel driving circuit includes a reset sub-phase t1, a data write sub-phase t2, and a light emitting sub-phase t3. In the initial sub-phase t0, a turning-off reset control signal is provided through the respective second reset control signal line rst2 to the gate electrode of the second reset transistor Tr2 to turn off the second reset transistor Tr2. A turning-off reset control signal is provided through the respective first reset control signal line rst1 to the gate electrode of the first reset transistor Tr1 and the gate electrode of the third reset transistor Tr3 to turn off the first reset transistor Tr1 and the third reset transistor Tr3. In the initial sub-phase t0, the respective first gate line GL1 is provided with a turning-off signal, thus the first transistor T1 is turned off.

In the reset sub-phase t1, a turning-on reset control signal is provided through the respective first reset control signal line rst1 to the gate electrode of the first reset transistor Tr1 to turn on the first reset transistor Tr1; allowing an initialization voltage signal from the respective first reset signal line Vint1 to pass from a first electrode of the first reset transistor Trl to a second electrode of the first reset transistor Tr1; and in turn to the node N4. The anode of the light emitting element LE is initialized. A turning-on reset control signal is provided through the respective first reset control signal line rst1 to the gate electrode of the third reset transistor Tr3 to turn on the third reset transistor Tr3; allowing an initialization voltage signal from the respective third reset signal line Vint3 to pass from a first electrode of the third reset transistor Tr3 to a second electrode of the third reset transistor Tr3; and in turn to the node N2. The node N2 is initialized. The second capacitor electrode Ce2 receives a high voltage signal from the respective voltage supply line Vdd. The first capacitor electrode Cel is charged in the reset sub-phase t1 due to an increasing voltage difference between the first capacitor electrode Cel and the second capacitor electrode Ce2. In the reset sub-phase t1, the respective first gate line GL1 is provided with a turning-off signal, thus the first transistor T1 is turned off. The respective light emitting control signal line em is provided with a high voltage signal to turn off the third transistor T3 and the fourth transistor T4.

In the data write sub-phase t2, a turning-on reset control signal is provided through the second reset control signal line rst2 to the gate electrode of the second reset transistor Tr2 to turn on the second reset transistor Tr2; allowing an initialization voltage signal from the respective second reset signal line Vint2 to pass from a first electrode of the second reset transistor Tr2 to a second electrode of the second reset transistor Tr2, and in turn to the second electrode of the driving transistor Td. The second electrode of the driving transistor Td is initialized.

In the data write sub-phase t2, the turning-off reset control signal is again provided through the respective first reset control signal line rst1 to the gate electrode of the first reset transistor Tr1 and the gate electrode of the third reset transistor Tr3 to turn off the first reset transistor Tr1 and the third reset transistor Tr3. The respective first gate line GL1 and the respective second gate line GL2 are provided with a turning-on signal, thus the first transistor T1 and the second transistor T2 are turned on. A first electrode of the driving transistor Td is connected with the second electrode of the second transistor T2. A gate electrode of the driving transistor Td is electrically connected with the first electrode of the second transistor T2. Because the second transistor T2 is turned on in the data write sub-phase t2, the gate electrode and the second electrode of the driving transistor Td are connected and short circuited, and only the PN junction between the gate electrode and a first electrode of the driving transistor Td is effective, thus rendering the driving transistor Td in a diode connecting mode. The first transistor T1 is turned on in the data write sub-phase t2. The data voltage signal transmitted through the respective data line DL is received by a first electrode of the first transistor T1, and in turn transmitted to the first electrode of the driving transistor Td, which is connected to the second electrode of the first transistor T1. A node N2 connecting to the first electrode of the driving transistor Td has a voltage level of the data voltage signal. Because only the PN junction between the gate electrode and a first electrode of the driving transistor Td is effective, the voltage level at the node N1 in the data write sub-phase t2 increase gradually to (Vdata+Vth), wherein the Vdata is the voltage level of the data voltage signal, and the Vth is the voltage level of the threshold voltage Th of the PN junction. The storage capacitor Cst is discharged because the voltage difference between the first capacitor electrode Ce1 and the second capacitor electrode Ce2 is reduced to a relatively small value. The respective light emitting control signal line em is provided with a high voltage signal to turn off the third transistor T3 and the fourth transistor T4.

In the light emitting sub-phase t3, a turning-off reset control signal is provided through the respective second reset control signal line rst2 to the gate electrode of the second reset transistor Tr2 to turn off the second reset transistor Tr2. A turning-off reset control signal is provided through the respective first reset control signal line rst1 to the gate electrode of the first reset transistor Tr1 and the gate electrode of the third reset transistor Tr3 to turn off the first reset transistor Trl and the third reset transistor Tr3. The respective first gate line GL1 and the respective second gate line GL2 are provided with a turning-off signal, the first transistor T1 and the second transistor T2 are turned off. The respective light emitting control signal line em is provided with a low voltage signal to turn on the third transistor T3 and the fourth transistor T4. The voltage level at the node N1 in the light emitting sub-phase t3 is maintained at (Vdata+Vth), the driving transistor Td is turned on by the voltage level, and working in the saturation area. A path is formed through the third transistor T3, the driving transistor Td, the fourth transistor T4, to the light emitting element LE. The driving transistor Td generates a driving current for driving the light emitting element LE to emit light. A voltage level at a node N3 connected to the second electrode of the driving transistor Td equals to a light emitting voltage of the light emitting element LE.

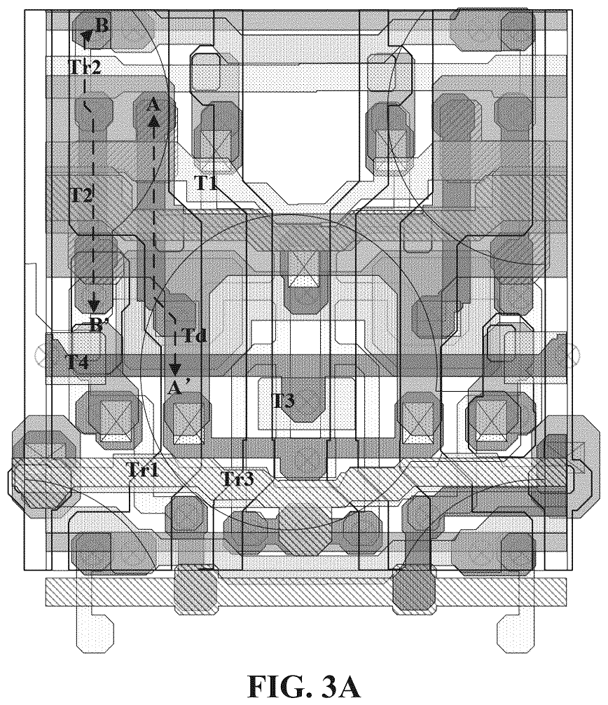

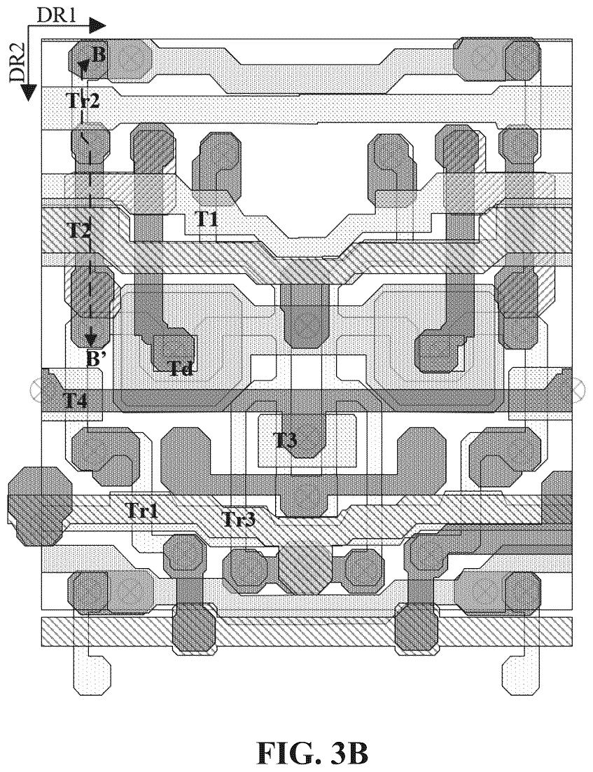

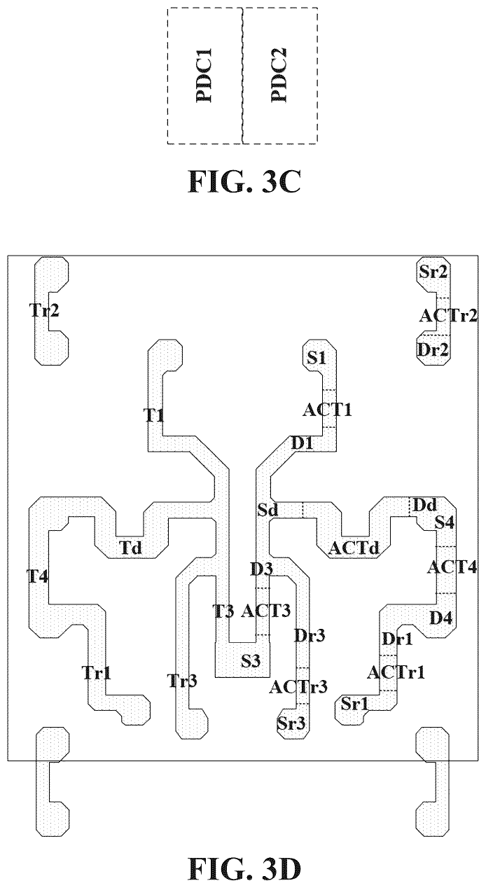

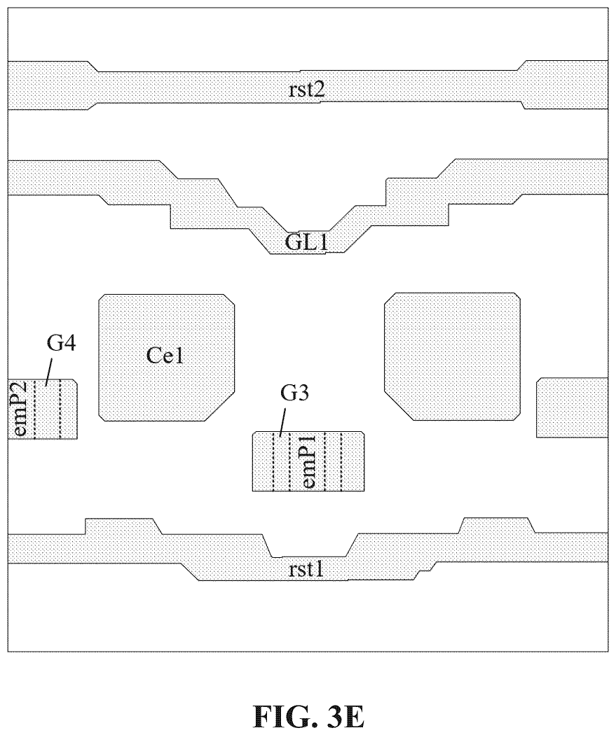

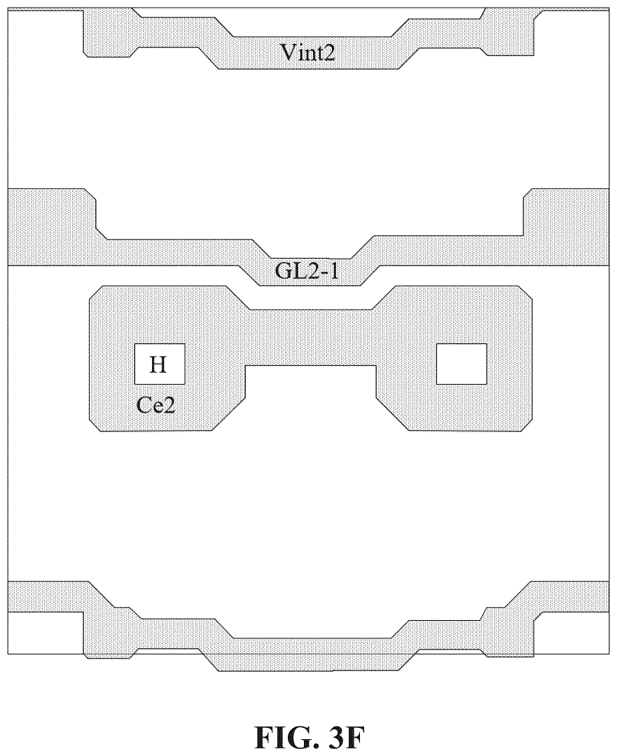

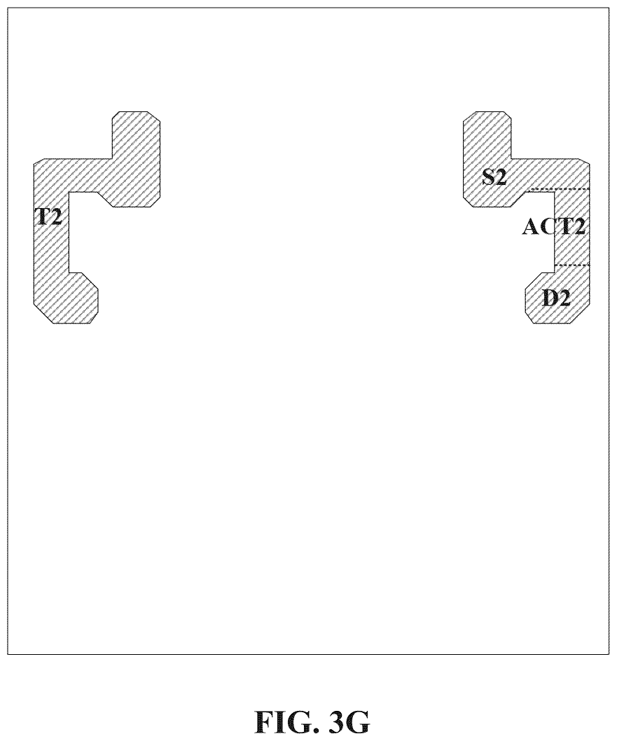

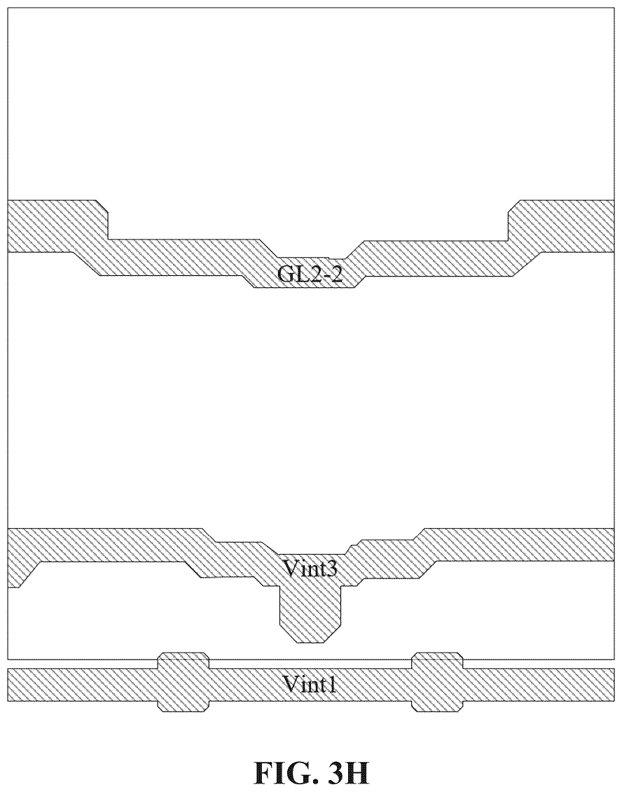

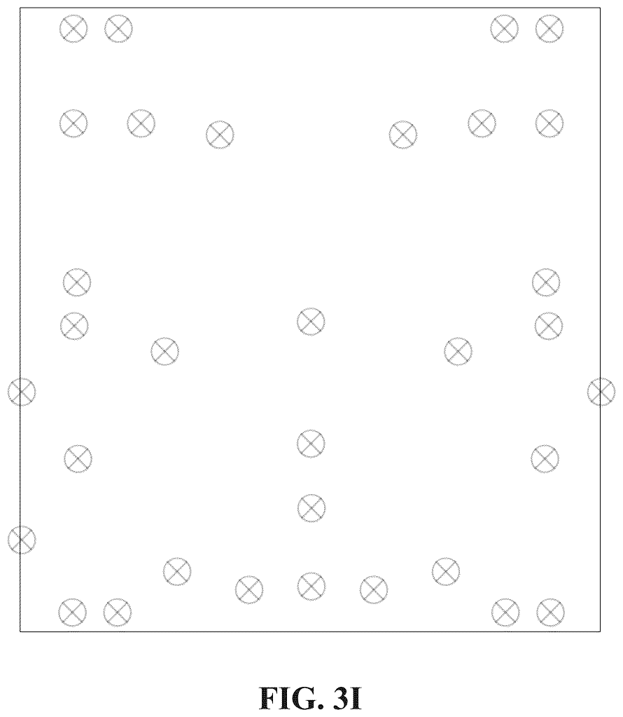

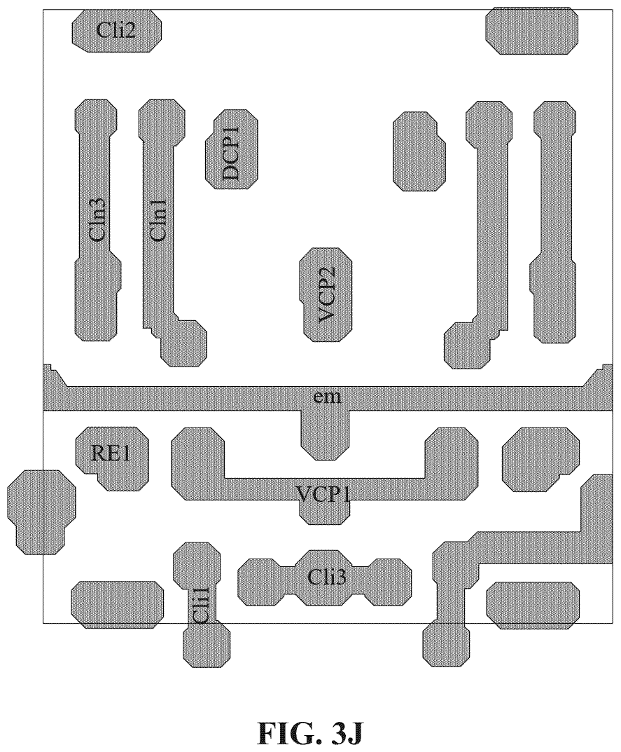

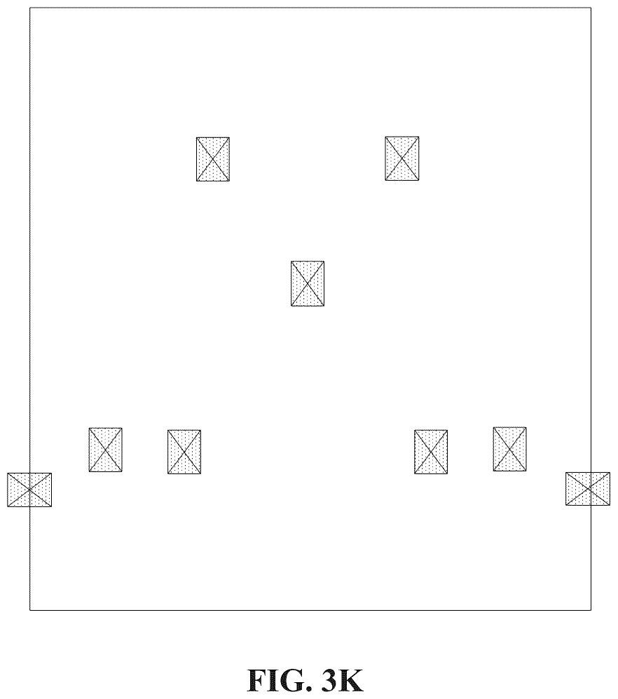

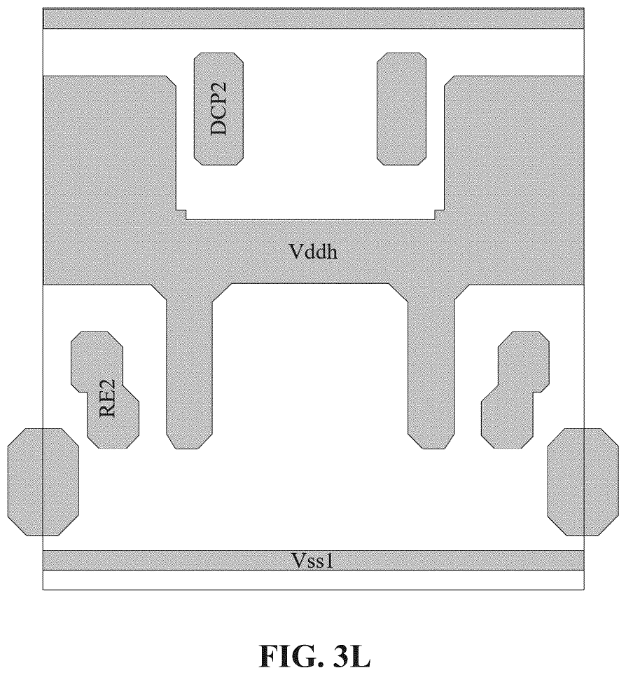

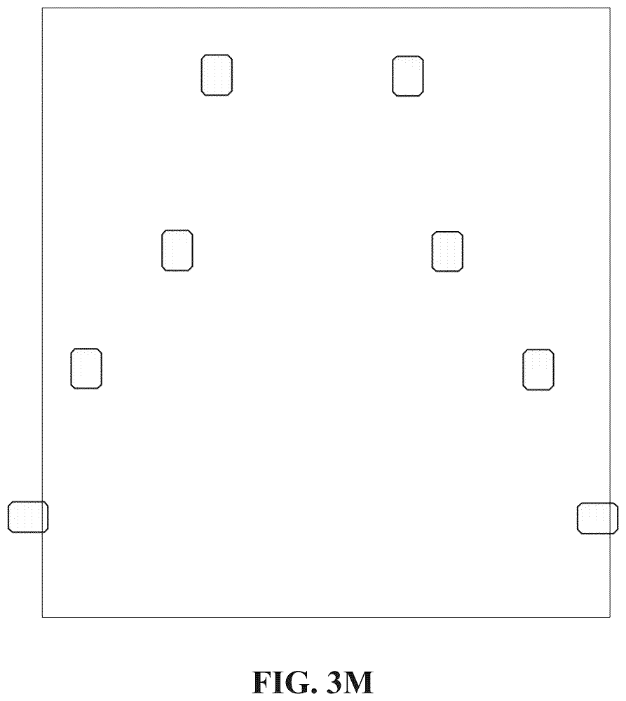

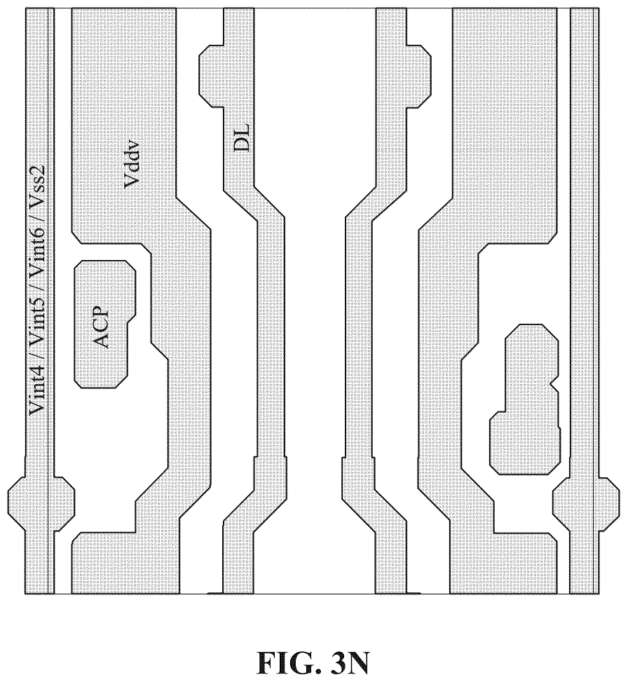

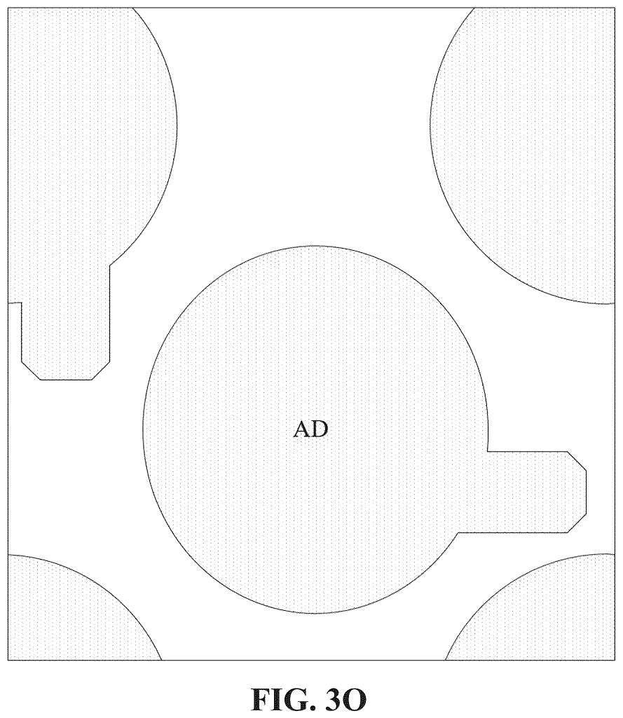

FIG. 3A is a diagram illustrating the structure of pixel driving circuits in an array substrate in some embodiments according to the present disclosure. FIG. 3B is a diagram illustrating the structure of a first semiconductor material layer, a first gate metal layer, a second gate metal layer, a second semiconductor material layer, a third gate metal layer, and a first signal line layer in the array substrate depicted in FIG. 3A. FIG. 3C is a schematic diagram illustrating an arrangement of pixel driving circuits in the array substrate depicted in FIG. 3A. FIG. 3A to FIG. 3C depict a portion of the array substrate having two adjacent pixel driving circuits, including PDC1 and PDC2.

FIG. 3D is a diagram illustrating the structure of a first semiconductor material layer in the array substrate depicted in FIG. 3A. FIG. 3E is a diagram illustrating the structure of a first gate metal layer in the array substrate depicted in FIG. 3A. FIG. 3F is a diagram illustrating the structure of a second gate metal layer in the array substrate depicted in FIG. 3A. FIG. 3G is a diagram illustrating the structure of a second semiconductor material layer in the array substrate depicted in FIG. 3A. FIG. 3H is a diagram illustrating the structure of a third gate metal layer in the array substrate depicted in FIG. 3A. FIG. 3I is a diagram illustrating the structure of a passivation layer in the array substrate depicted in FIG. 3A. FIG. 3J is a diagram illustrating the structure of a first signal line layer in the array substrate depicted in FIG. 3A.

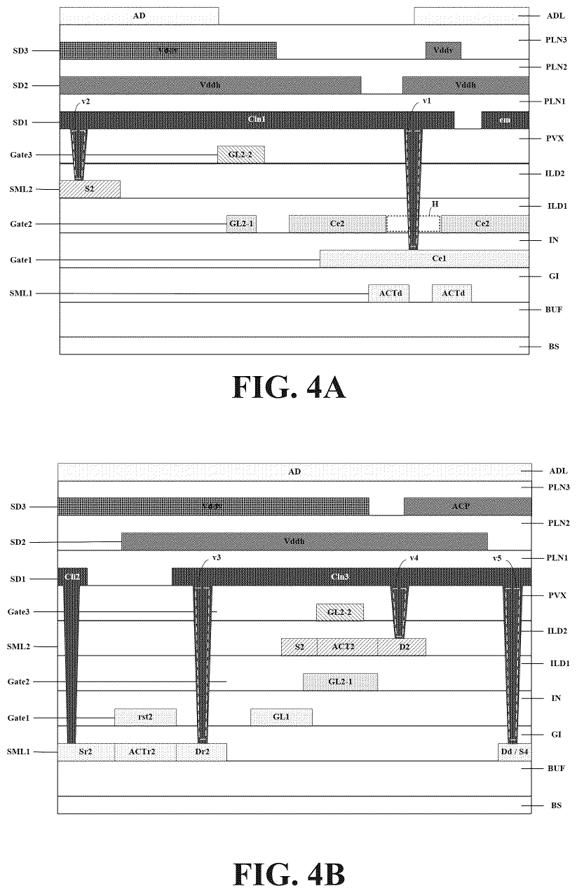

FIG. 3K is a diagram illustrating the structure of a first planarization layer in the array substrate depicted in FIG. 3A. FIG. 3L is a diagram illustrating the structure of a second signal line layer in the array substrate depicted in FIG. 3A. FIG. 3M is a diagram illustrating the structure of a second planarization layer in the array substrate depicted in FIG. 3A. FIG. 3N is a diagram illustrating the structure of a third signal line layer in the array substrate depicted in FIG. 3A. FIG. 3O is a diagram illustrating the structure of an anode layer in the array substrate depicted in FIG. 3A. FIG. 4A is a cross-sectional view along an A-A′ line in FIG. 3A. FIG. 4B is a cross-sectional view along a B-B′ line in FIG. 3A.

Referring to FIG. 3A to FIG. 3N, FIG. 4A, and FIG. 4B, the array substrate in some embodiments includes a base substrate BS, a buffer layer BUF on the base substrate BS, a first semiconductor material layer SML1 on a side of the buffer layer BUF away from the base substrate BS, a gate insulating layer GI on a side of the first semiconductor material layer SML1 away from the base substrate BS, a first gate metal layer Gate1 on a side of the gate insulating layer GI away from the first semiconductor material layer SML1, an insulating layer IN on a side of the first gate metal layer Gate1 away from the gate insulating layer GI, a second gate metal layer Gate2 on a side of the insulating layer IN away from the first gate metal layer Gate1, a first inter-layer dielectric layer ILD1 on a side of the second gate metal layer Gate2 away from the insulating layer IN, a second semiconductor material layer SML2 on a side of the first inter-layer dielectric layer ILD1 away from the second gate metal layer Gate2, a second inter-layer dielectric layer ILD2 on a side of the second semiconductor material layer SML2 away from the first inter-layer dielectric layer ILD1, a third gate metal layer Gate3 on a side of the second inter-layer dielectric layer ILD2 away from the second semiconductor material layer SML2, a passivation layer PVX on a side of the third gate metal layer Gate3 away from the second inter-layer dielectric layer ILD2, a first signal line layer SD1 on a side of the passivation layer PVX away from the third gate metal layer Gate3, a first planarization layer PLN1 on a side of the first signal line layer SD1 away from the passivation layer PVX, a second signal line layer SD2 on a side of the first planarization layer PLN1 away from the first signal line layer SD1, a second planarization layer PLN2 on a side of the second signal line layer SD2 away from the first planarization layer PLN1, a third signal line layer SD3 on a side of the second planarization layer PLN2 away from the second signal line layer SD2, a third planarization layer PLN3 on a side of the third signal line layer SD3 away from the second planarization layer PLN2, and an anode layer ADL on a side of the third planarization layer PLN3 away from the third signal line layer SD3.

Referring to FIG. 2A, FIG. 3A, FIG. 3D, FIG. 4A, and FIG. 4B, the first semiconductor material layer SML1 in some embodiments includes at least active layers of multiple transistors of the pixel driving circuit, including the first transistor T1, the third transistor T3, the fourth transistor T4, the first reset transistor Tr1, the second reset transistor Tr2, the third reset transistor Tr3, and the driving transistor Td. Optionally, the first semiconductor material layer SML1 further includes at least respective portions of first electrodes of multiple transistors of the pixel driving circuit, including the first transistor T1, the third transistor T3, the fourth transistor T4, the first reset transistor Tr1, the second reset transistor Tr2, the third reset transistor Tr3, and the driving transistor Td. Optionally, the first semiconductor material layer SML1 further includes at least respective portions of second electrodes of multiple transistors of the pixel driving circuit, including the first transistor T1, the third transistor T3, the fourth transistor T4, the first reset transistor Tr1, the second reset transistor Tr2, the third reset transistor Tr3, and the driving transistor Td. Optionally, the first semiconductor material layer SML1 includes active layers, first electrodes, and second electrodes of multiple transistors of the pixel driving circuit, including the first transistor T1, the third transistor T3, the fourth transistor T4, the first reset transistor Tr1, the second reset transistor Tr2, the third reset transistor Tr3, and the driving transistor Td. Various appropriate semiconductor materials may be used for making the first semiconductor material layer SML1. Examples of the semiconductor materials for making the first semiconductor material layer SML1 include silicon-based semiconductor materials such as polycrystalline silicon, single-crystal silicon, and amorphous silicon.

In FIG. 3D, a pixel driving circuit corresponding to PDC2 in FIG. 3C is annotated with labels indicating components of each of multiple transistors (T1, T3, T4, Tr1, Tr2, Tr3, and Td) in the pixel driving circuit. For example, the first transistor T1 includes an active layer ACT1, a first electrode S1, and a second electrode D1. The third transistor T3 includes an active layer ACT3, a first electrode S3, and a second electrode D3. The fourth transistor T4 includes an active layer ACT4, a first electrode S4, and a second electrode D4. The first reset transistor Trl includes an active layer ACTr1, a first electrode Sr1, and a second electrode Dr1. The second reset transistor Tr2 includes an active layer ACTr2, a first electrode Sr2, and a second electrode Dr2. The third reset transistor Tr3 includes an active layer ACTr3, a first electrode Sr3, and a second electrode Dr3. The driving transistor Td includes an active layer ACTd, a first electrode Sd, and a second electrode Dd.

Optionally, the active layers (ACT1, ACT3, ACT4, ACTr1, ACTr2, ACTr3, and ACTd), the first electrodes (S1, S3, S4, Sr1, Sr2, Sr3, and Sd), and the second electrodes (D1, D3, D4, Dr1, Dr2, Dr3, and Dd) of the respective transistors (T1, T3, T4, Tr1, Tr2, Tr3, and Td) are in a same layer.

In some embodiments, the active layers (ACT1, ACT3, ACT4, ACTr1, ACTr3, and ACTd), at least portions of the first electrodes (S1, S3, S4, Sr1, Sr3, and Sd), and at least portions of the second electrodes (D1, D3, D4, Dr1, Dr3, and Dd) of multiple transistors (T1, T3, T4, Tr1, Tr3, and Td) in the pixel driving circuit are parts of a unitary structure.

Optionally, a part of the second reset transistor Tr2 (ACTr2, Sr2, Dr2) in the first semiconductor material layer is spaced apart from the unitary structure (T1, T3, T4, Tr1, and Td) in a same pixel driving circuit. As shown in FIG. 3D, in some embodiments, the active layers (ACT1, ACT3, ACT4, ACTr1, ACTr3, and ACTd), at least portions of the first electrodes (S1, S3, S4, Sr1, Sr3, and Sd), and at least portions of the second electrodes (D1, D3, D4, Dr1, Dr3, and Dd) of multiple transistors (T1, T3, T4, Tr1, Tr3, and Td) in two adjacent pixel driving circuits are parts of a unitary structure.

Referring to FIG. 2A, FIG. 3A, FIG. 3E, FIG. 4A, and FIG. 4B, the first gate metal layer Gate1 in some embodiments includes a plurality of first gate lines (e.g., a respective first gate line GL1), a plurality of first reset control signal lines (e.g., a respective first reset control signal line rst1), a plurality of second reset control signal lines (e.g., a respective second reset control signal line rst2), a first light emitting control electrode pad emP1, a second light emitting control electrode pad emP2, and a first capacitor electrode Cel of the storage capacitor Cst in the pixel driving circuit.

In some embodiments, the first light emitting control electrode pad emP1 includes a gate electrode G3 of the third transistor T3. Optionally, the first light emitting control electrode pad emP1 includes gate electrodes of third transistors of a first adjacent pixel driving circuit and a second adjacent pixel driving circuit in a same row. In some embodiments, the second light emitting control electrode pad emP2 includes a gate electrode G4 of the fourth transistor T4. Optionally, the second light emitting control electrode pad emP2 includes gate electrodes of fourth transistors of the first adjacent pixel driving circuit and a third adjacent pixel driving circuit in a same row. The third adjacent pixel driving circuit, the first adjacent pixel driving circuit, and the second adjacent pixel driving circuit are arranged sequentially in the same row.

Various appropriate electrode materials and various appropriate fabricating methods may be used to make the first gate metal layer Gate1. For example, a conductive material may be deposited on the substrate by a plasma-enhanced chemical vapor deposition (PECVD) process and patterned. Examples of appropriate conductive materials for making the first gate metal layer Gate1 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of first gate lines (e.g., the respective first gate line GL1), the plurality of first reset control signal lines (e.g., the respective first reset control signal line rst1), the plurality of second reset control signal lines (e.g., the respective second reset control signal line rst2), the first light emitting control electrode pad emP1, the second light emitting control electrode pad emP2, and the first capacitor electrode Cel of the storage capacitor Cst in the pixel driving circuit are in a same layer.

As used herein, the term “same layer” refers to the relationship between the layers simultaneously formed in the same step. In one example, the plurality of first gate lines and the first capacitor electrode Cel are in a same layer when they are formed as a result of one or more steps of a same patterning process performed in a same layer of material. In another example, the plurality of first gate lines and the first capacitor electrode Cel can be formed in a same layer by simultaneously performing the step of forming the plurality of first gate lines, and the step of forming the first capacitor electrode Cel. The term “same layer” does not always mean that the thickness of the layer or the height of the layer in a cross-sectional view is the same.

In some embodiments, referring to FIG. 3A, FIG. 3B, FIG. 3E, FIG. 3J, and FIG. 4A, the first light emitting control electrode pad emP1 and the second light emitting control electrode pad emP2 are connected to a respective light emitting control signal line em of a plurality of light emitting control signal lines. Optionally, the first light emitting control electrode pad emP1 and the second light emitting control electrode pad emP2 are in the first gate metal layer Gate1. Optionally, the respective light emitting control signal line em is in the first signal line layer SD1. In one example, the respective light emitting control signal line em is connected to the first light emitting control electrode pad emP1 through a via extending through the passivation layer PVX, the second inter-layer dielectric layer ILD2, the first inter-layer dielectric layer ILD1, and the insulating layer IN. In another example, the respective light emitting control signal line em is connected to the second light emitting control electrode pad emP2 through a via extending through the passivation layer PVX, the second inter-layer dielectric layer ILD2, the first inter-layer dielectric layer ILD1, and the insulating layer IN.

Referring to FIG. 2A, FIG. 3A, FIG. 3F, FIG. 4A, and FIG. 4B, the second gate metal layer Gate2 in some embodiments includes at least portions of a plurality of second gate lines (e.g., a respective second gate line first branch GL2-1), a plurality of second reset signal lines (e.g., a respective second reset signal line Vint2), and a second capacitor electrode Ce2 of the storage capacitor Cst in the pixel driving circuit. Various appropriate electrode materials and various appropriate fabricating methods may be used to make the second gate metal layer Gate2. For example, a conductive material may be deposited on the substrate by a plasma-enhanced chemical vapor deposition (PECVD) process and patterned. Examples of appropriate conductive materials for making the second gate metal layer Gate2 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the at least portions of the plurality of second gate lines (e.g., a respective second gate line first branch GL2-1), the plurality of second reset signal lines (e.g., the respective second reset signal line Vint2), and the second capacitor electrode Ce2 of the storage capacitor Cst in the pixel driving circuit are in a same layer.

Referring to FIG. 2A, FIG. 3A, FIG. 3G, FIG. 4A, and FIG. 4B, the second semiconductor material layer SML2 in some embodiments includes at least an active layer ACT2 of the second transistor T2 in the pixel driving circuit. Optionally, the second semiconductor material layer SML2 further includes at least a portion of a first electrode S2 of the second transistor T2 in the pixel driving circuit. Optionally, the second semiconductor material layer SML2 further includes at least a portion of a second electrode D2 of the second transistor T2 in the pixel driving circuit. Optionally, the second semiconductor material layer SML2 includes the active layer ACT2, the first electrode S2, and the second electrode D2 of the second transistor T2. In the present array substrate, at least the active layer ACT2 of the second transistor T2 are in a layer different from at least the active layers of other transistors of the pixel driving circuit. Various appropriate semiconductor materials may be used for making the second semiconductor material layer SML2. Examples of the semiconductor materials for making the second semiconductor material layer SML2 include metal oxide-based semiconductor material such as indium gallium zinc oxide and metal oxynitride-based semiconductor materials such as zinc oxynitride.

In FIG. 3G, a pixel driving circuit corresponding to PDC1 in FIG. 3B is annotated with labels indicating components of the second transistor in the pixel driving circuit. For example, the second transistor T2 includes an active layer ACT2, a first electrode S2, and a second electrode D2. Optionally, the active layer ACT2, the first electrode S2, and the second electrode D2 of the second transistor T2 are in a same layer.

Referring to FIG. 2A, FIG. 3A, FIG. 3H, FIG. 4A, and FIG. 4B, the third gate metal layer Gate3 in some embodiments includes at least portions of a plurality of second gate lines (e.g., a respective second gate line second branch GL2-2), a plurality of first reset signal lines (e.g., a respective first reset signal line Vint1), and a plurality of third reset signal lines (e.g., a respective third reset signal line Vint3). Various appropriate electrode materials and various appropriate fabricating methods may be used to make the third gate metal layer Gate3. For example, a conductive material may be deposited on the substrate by a plasma-enhanced chemical vapor deposition (PECVD) process and patterned. Examples of appropriate conductive materials for making the third gate metal layer Gate3 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like.

FIG. 3I illustrates vias extending through the passivation layer in the array substrate depicted in FIG. 3A.

Referring to FIG. 2A, FIG. 3A, FIG. 3J, FIG. 4A, and FIG. 4B, the first signal line layer SD1 in some embodiments includes a plurality of light emitting control signal lines (e.g., a respective light emitting control signal line em); a first voltage connecting pad VCP1; a second voltage connecting pad VCP2; a first data connecting pad DCP1; a first node connecting line Cln1; a third node connecting line Cln3; a first relay electrode RE1; a first reset signal connecting line Cli1; a second reset signal connecting line Cli2; and a third reset signal connecting line Cli3.

Various appropriate conductive materials and various appropriate fabricating methods may be used to make the first signal line layer SD1. For example, a conductive material may be deposited on the substrate by a plasma-enhanced chemical vapor deposition (PECVD) process and patterned. Examples of appropriate conductive materials for making the first signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the first signal line layer includes a plurality of sub-layers stacked together. In one example, the first signal line layer includes a stacked titanium/aluminum/titanium multi-layer structure. In another example, the first signal line layer includes a stacked molybdenum/aluminum/molybdenum multi-layer structure. Optionally, the plurality of light emitting control signal lines (e.g., the respective light emitting control signal line em); the first voltage connecting pad VCP1; the second voltage connecting pad VCP2; the first data connecting pad DCP1; the first node connecting line Cln1; the third node connecting line Cln3; the first relay electrode RE1; the first reset signal connecting line Cli1; the second reset signal connecting line Cli2; and the third reset signal connecting line Cli3 are in a same layer.

In some embodiments, the first node connecting line Cln1 connects multiple components of the pixel driving circuit to the node N1. Referring to FIG. 4A, the first node connecting line Cln1 is connected to the first capacitor electrode Cel through a first via v1, and connected to the second transistor T2 (e.g., to the first electrode S2 of the second transistor T2) through a second via v2. Optionally, the first node connecting line Cln1 corresponds to the node N1 depicted in FIG. 2A.

In some embodiments, an orthographic projection of the second electrode Dr3 of the third reset transistor Tr3 on a base substrate BS at least partially overlaps with an orthographic projection of the first voltage connecting pad VCP1 on the base substrate BS. The inventors of the present disclosure discover that this structure is conducive in stabilizing the voltage level at the node N2 by having a constant voltage at the first voltage connecting pad VCP1.

Referring to FIG. 2A, FIG. 3A, FIG. 3E, FIG. 3F, FIG. 4A, and FIG. 4B, in some embodiments, in a hole region H, a portion of the second capacitor electrode Ce2 is absent.

Optionally, an orthographic projection of the second capacitor electrode Ce2 on a base substrate BS substantially (e.g., at least 80%, at least 85%, at least 90%, at least 95%, at least 98%, at least 99%, or 100%) covers, with a margin, an orthographic projection of the first capacitor electrode Cel on the base substrate BS except for the hole region H in which a portion of the second capacitor electrode Ce2 is absent. Optionally, the first via v1 extends through the passivation layer PVX, the second inter-layer dielectric layer ILD2, the first inter-layer dielectric layer ILD1, the hole region H, and the insulating layer IN.

In some embodiments, the first node connecting line Cln1 crosses over a respective second gate line of the plurality of second gate lines. As shown in FIG. 3A, FIG. 3B, and FIG. 4A, the first node connecting line Cln1 crosses over the respective second gate line first branch GL2-1 in the second gate metal layer Gate2, and the respective second gate line second branch GL2-2 in the third gate metal layer Gate3.

In some embodiments, referring to FIG. 4B, the third node connecting line Cln3 is connected to a second electrode Dr2 of the second reset transistor Tr2 through a third via v3, connected to a second electrode D2 of the second transistor T2 through a fourth via v4, and connected to a second electrode Dd of the driving transistor Td and a first electrode S4 of the fourth transistor T4 through a fifth via v5. Optionally, the third node connecting line Cln3 corresponds to the node N3 depicted in FIG. 2A. Optionally, the third node connecting line Cln3 crosses over a respective second gate line of the plurality of second gate lines. As shown in FIG. 3A, FIG. 3B, and FIG. 4B, the third node connecting line Cln3 crosses over the respective second gate line first branch GL2-1 in the second gate metal layer Gate2, and the respective second gate line second branch GL2-2 in the third gate metal layer Gate3.

In some embodiments, an orthographic projection of the third node connecting line Cln3 on a base substrate BS at least partially (e.g., at least 50%, at least 55%, at least 60%, at least 65%, at least 70%, at least 75%, at least 80%, at least 85%, at least 90%, at least 95%, at least 98%, or at least 99%) overlaps with an orthographic projection of the active layer ACT2 of the second transistor T2 on the base substrate. Optionally, the third node connecting line Cln3 extends along a direction substantially parallel to a direction along which the active layer ACT2 of the second transistor T2 extends. Optionally, the orthographic projection of the third node connecting line Cln3 on a base substrate BS at least partially overlaps with an orthographic projection of the first electrode S2 of the second transistor T2 on the base substrate. Optionally, the orthographic projection of the third node connecting line Cln3 on a base substrate BS at least partially overlaps with an orthographic projection of the second electrode D2 of the second transistor T2 on the base substrate. As used herein, the term “substantially parallel” means that an angle is in the range of 0 degree to approximately 45 degrees, e.g., 0 degree to approximately 5 degrees, 0 degree to approximately 10 degrees, 0 degree to approximately 15 degrees, 0 degree to approximately 20 degrees, 0 degree to approximately 25 degrees, 0 degree to approximately 30 degrees.

In the present array substrate, the second electrode D1 of the first transistor T1, the first electrode Sd of the driving transistor Td, the second electrode D3 of the third transistor T3, and the second electrode Dr3 of the third reset transistor Tr3 are in a same layer, e.g., in the first semiconductor material layer SML1. In some embodiments, the second electrode D1 of the first transistor T1, the first electrode Sd of the driving transistor Td, the second electrode D3 of the third transistor T3, and the second electrode Dr3 of the third reset transistor Tr3 are parts of a unitary structure. In some embodiments, the second electrode D1 of the first transistor T1, the first electrode Sd of the driving transistor Td, the second electrode D3 of the third transistor T3, and the second electrode Dr3 of the third reset transistor Tr3 are connected to each other in the first semiconductor material layer SML1. The second electrode D1 of the first transistor T1, the first electrode Sd of the driving transistor Td, the second electrode D3 of the third transistor T3, and the second electrode Dr3 of the third reset transistor Tr3 are connected to each other by one or more portions of the first semiconductor material layer SML1, e.g., without any connecting line in a layer different from the first semiconductor material layer SML1.

In some embodiments, a respective light emitting control signal line em of a plurality of light emitting control signal lines is connected to the first light emitting control electrode pad emP1 and the second light emitting control electrode pad emP2 in the first gate metal layer Gate1.

FIG. 3K illustrates vias extending through the first planarization layer in the array substrate depicted in FIG. 3A.

Referring to FIG. 2A, FIG. 3A, FIG. 3B, FIG. 3L, FIG. 4A, and FIG. 4B, the second signal line layer SD2 in some embodiments includes a plurality of first voltage supply lines (e.g., a respective first voltage supply line Vddh), a plurality of first low voltage supply lines (e.g., a respective first low voltage supply line Vss1), a second relay electrode RE2, and a second data connecting pad DCP2. Various appropriate conductive materials and various appropriate fabricating methods may be used to make the second signal line layer SD2. For example, a conductive material may be deposited on the substrate by a plasma-enhanced chemical vapor deposition (PECVD) process and patterned. Examples of appropriate conductive materials for making the second signal line layer SD2 include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In one example, the second signal line layer includes a stacked titanium/aluminum/titanium multi-layer structure. In another example, the second signal line layer includes a stacked molybdenum/aluminum/molybdenum multi-layer structure. Optionally, the plurality of first voltage supply lines (e.g., the respective first voltage supply line Vddh), the second relay electrode RE2, and the second data connecting pad DCP2 are in a same layer.

FIG. 3M illustrates vias extending through the second planarization layer in the array substrate depicted in FIG. 3A.

Referring to FIG. 2A, FIG. 3A, FIG. 3N, FIG. 4A, and FIG. 4B, the third signal line layer SD3 in some embodiments includes a plurality of second voltage supply lines (e.g., a respective second voltage supply line Vddv), an anode contact pad ACP, a plurality of data lines (e.g., a respective data line DL), a plurality of fourth reset signal lines (e.g., a respective fourth reset signal line Vint4), a plurality of fifth reset signal lines (e.g., a respective fifth reset signal line Vint5), a plurality of sixth reset signal lines (e.g., a respective sixth reset signal line Vint6), and a plurality of second low voltage supply lines (e.g., a respective second low voltage supply line Vss2). In some embodiments, the respective first voltage supply line Vddh and the respective second voltage supply line Vddv are configured to provide a first reference voltage signal (e.g., a high reference voltage signal). Optionally, the respective low voltage supply line Vss is configured to provide a second reference voltage signal (e.g., a low reference voltage signal). Optionally, the first reference voltage signal is a constant voltage signal, the second reference voltage signal is a constant voltage signal, the first reference voltage signal has a voltage level higher than a voltage level of the second reference voltage signal.

Various appropriate conductive materials and various appropriate fabricating methods may be used to make the third signal line layer SD3. For example, a conductive material may be deposited on the substrate by a plasma-enhanced chemical vapor deposition (PECVD) process and patterned. Examples of appropriate conductive materials for making the third signal line layer SD3 include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In one example, the second signal line layer includes a stacked titanium/aluminum/titanium multi-layer structure. In another example, the second signal line layer includes a stacked molybdenum/aluminum/molybdenum multi-layer structure. Optionally, the plurality of second voltage supply lines (e.g., the respective second voltage supply line Vddv), the anode contact pad ACP, the plurality of data lines (e.g., the respective data line DL), the plurality of fourth reset signal lines (e.g., the respective fourth reset signal line Vint4), the plurality of fifth reset signal lines (e.g., the respective fifth reset signal line Vint5), the plurality of sixth reset signal lines (e.g., the respective sixth reset signal line Vint6), and the plurality of low voltage supply lines (e.g., the respective low voltage supply line Vss) are in a same layer.

Referring to FIG. 2A, FIG. 3A, FIG. 3O, FIG. 4A, and FIG. 4B, the anode layer ADL in some embodiments includes a plurality of anodes AD.

Referring to FIG. 2A, FIG. 3A, FIG. 3B, FIG. 3J, FIG. 3L, FIG. 3N, FIG. 4A, and FIG. 4B, in some embodiments, the plurality of first voltage supply lines and the plurality of second voltage supply lines are interconnected to each other, forming a voltage supply network. A respective first voltage supply line Vddh of the plurality of first voltage supply lines is connected to the first voltage connecting pad VCP1, the first voltage connecting pad VCP1 is connected to the first electrode of the third transistor T3, thereby providing a voltage supply signal to the first electrode of the third transistor T3. A respective first voltage supply line Vddh of the plurality of first voltage supply lines is connected to the second voltage connecting pad VCP2, the second voltage connecting pad VCP2 is connected to the second capacitor electrode Ce2 of the storage capacitor Cst, thereby providing a voltage supply signal to the second capacitor electrode Ce2 of the storage capacitor Cst.

In some embodiments, the first reset signal connecting line Cli1 connects a respective first reset signal line Vint1 of a plurality of first reset signal lines to the first electrode Sr1 of the first reset transistor Tr1. The first reset signal connecting line Cli1 is configured to transmit a reset signal from the respective first reset signal line Vint1 to the first electrode Sr1 of the first reset transistor Tr1.

In some embodiments, the second reset signal connecting line Cli2 connects a respective second reset signal line Vint2 of a plurality of second reset signal lines to the first electrode Sr2 of the second reset transistor Tr2. The second reset signal connecting line Cli2 is configured to transmit a reset signal from the respective second reset signal line Vint2 to the first electrode Sr1 of the second reset transistor Tr2.

In some embodiments, the third reset signal connecting line Cli3 connects a respective third reset signal line Vint3 of a plurality of third reset signal lines to the first electrode Sr3 of the third reset transistor Tr3. The third reset signal connecting line Cli3 is configured to transmit a reset signal from the respective third reset signal line Vint3 to the first electrode Sr3 of the third reset transistor Tr3. In one example, the third reset signal connecting line Cli3 is connected to first electrodes of third reset transistors in two adjacent pixel driving circuits in a same row, and configured to transmit a reset signal from the respective third reset signal line Vint3 to the first electrodes of the third reset transistors in two adjacent pixel driving circuits in the same row.

In some embodiments, the first relay electrode RE1 is connected to the second electrode D4 of the fourth transistor T4 (and/or the second electrode Dr1 of the first reset transistor Tr1), and is connected to the second relay electrode RE2. The second relay electrode is connected to the first relay electrode RE1, and is connected to the anode contact pad ACP. In one example, the anode contact pad ACP is in the third signal line layer SD3, the second relay electrode RE2 is in the second signal line layer SD2, and the first relay electrode RE1 is in the first signal line layer SD1. In another example, the anode contact pad ACP is connected to the second relay electrode RE2 through a via extending through the second planarization layer PLN2, the second relay electrode RE2 is connected to the first relay electrode RE1 through a via extending through the first planarization layer PLN1, and the first relay electrode RE1 is connected to the second electrode D4 of the fourth transistor T4 (and/or the second electrode Dr1 of the first reset transistor Tr1) through a via extending through the passivation layer PVX, the second inter-layer dielectric layer ILD2, the first inter-layer dielectric layer ILD1, the insulating layer IN, and the gate insulating layer GI.

In some embodiments, the first data connecting pad DCP1 is connected to the first electrode S1 of the first transistor T1, and is connected to the second data connecting pad DCP2. The second data connecting pad DCP2 is connected to the first data connecting pad DCP1, and is connected to a respective data line DL of the plurality of data lines. In one example, the first data connecting pad DCP1 is in the first signal line layer SD1, the second data connecting pad DCP2 is in the second signal line layer SD2, and the respective data line DL is in the third signal line layer SD3. In another example, the respective data line DL is connected to the second data connecting pad DCP2 through a via extending through the second planarization layer PLN2, the second data connecting pad DCP2 is connected to the first data connecting pad DCP1 through a via extending through the first planarization layer PLN1, and the first data connecting pad DCP1 is connected to the first electrode S1 of the first transistor T1 through a via extending through the passivation layer PVX, the second inter-layer dielectric layer ILD2, the first inter-layer dielectric layer ILD1, the insulating layer IN, and the gate insulating layer GI.

In the present array substrate, the respective light emitting control signal line em is not in the first gate metal layer, but in the first signal line layer. In the present array substrate, referring to FIG. 3A, FIG. 3B, and FIG. 3D, the second electrode D1 of the first transistor T1, the first electrode Sd of the driving transistor Td, the second electrode D3 of the third transistor T3, and the second electrode Dr3 of the third reset transistor Tr3 are in a same layer, e.g., in the first semiconductor material layer SML1. In some embodiments, the second electrode D1 of the first transistor T1, the first electrode Sd of the driving transistor Td, the second electrode D3 of the third transistor T3, and the second electrode Dr3 of the third reset transistor Tr3 are parts of a unitary structure. In some embodiments, the second electrode D1 of the first transistor T1, the first electrode Sd of the driving transistor Td, the second electrode D3 of the third transistor T3, and the second electrode Dr3 of the third reset transistor Tr3 are connected to each other in the first semiconductor material layer SML1. The second electrode D1 of the first transistor T1, the first electrode Sd of the driving transistor Td, the second electrode D3 of the third transistor T3, and the second electrode Dr3 of the third reset transistor Tr3 are connected to each other by one or more portions of the first semiconductor material layer SML1, e.g., without any connecting line in a layer different from the first semiconductor material layer SML1.

The inventors of the present disclosure discover that the unique and intricate structure of the present array substrate results in a significantly reduced parasitic capacitance, for example, between components in the first signal line layer and components in the first gate metal layer, resulting in a greatly improved display quality.

In some embodiments, referring to FIG. 3A to FIG. 3N, corresponding layers of a first pixel driving circuit (e.g., PDC1 in FIG. 3C) and corresponding layers of a second pixel driving circuit (e.g., PDC2 in FIG. 3C) directly adjacent to each other and in the present stage (e.g., in a same row) have a substantially (e.g., at least 80% symmetrical, at least 85% symmetrical, at least 90% symmetrical, at least 95% symmetrical, at least 98% symmetrical, at least 99% symmetrical, or completely symmetrical) mirror symmetry with respect to each other, e.g., about a plane perpendicular to a main surface of the array substrate and substantially parallel to the plurality of data lines.

As used herein, the term “corresponding layers of a first pixel driving circuit and corresponding layers of a second pixel driving circuit” is not intended to include layers that are not parts of the pixel driving circuits. For example, the “corresponding layers of a first pixel driving circuit and corresponding layers of a second pixel driving circuit” do not include an anode layer or a pixel definition layer. In some embodiments, the “corresponding layers of a first pixel driving circuit and corresponding layers of a second pixel driving circuit” do not include a third signal line layer. In some embodiments, the “corresponding layers of a first pixel driving circuit and corresponding layers of a second pixel driving circuit” do not include a second signal line layer. In some embodiments, the “corresponding layers of a first pixel driving circuit and corresponding layers of a second pixel driving circuit” do not include a first signal line layer. In some embodiments, the “corresponding layers of a first pixel driving circuit and corresponding layers of a second pixel driving circuit” do not include a third gate metal layer. In some embodiments, the “corresponding layers of a first pixel driving circuit and corresponding layers of a second pixel driving circuit” do not include a second gate metal layer.

In one example, the “corresponding layers of a first pixel driving circuit and corresponding layers of a second pixel driving circuit” refer to at least one conductive layer of the first pixel driving circuit and at least one conductive layer of a second pixel driving circuit. In one specific example, “corresponding layers” include at least one of a first semiconductor material layer, a first gate metal layer, a second gate metal layer, a second semiconductor material layer, a third gate metal layer, a first signal line layer, a second signal line layer, or a third signal line layer. In another specific example, “corresponding layers” further include at least one of a gate insulating layer, an insulating layer, a first inter-layer dielectric layer, a second inter-layer dielectric layer, a passivation layer, a first planarization layer, or a second planarization layer. In another specific example, the “corresponding layers of a first pixel driving circuit and corresponding layers of a second pixel driving circuit” include the first semiconductor material layer. In another specific example, the “corresponding layers of a first pixel driving circuit and corresponding layers of a second pixel driving circuit” include the first gate metal layer. In another specific example, the “corresponding layers of a first pixel driving circuit and corresponding layers of a second pixel driving circuit” include the second semiconductor material layer.

In related array substrates, the plurality of light emitting control signal lines are typically in the first gate metal layer, and a respective light emitting control signal line of the plurality of light emitting control signal lines typically includes gate electrodes of the third transistor and the fourth transistor. The related array substrates typically include a voltage connecting line that crosses over the respective light emitting control signal line. The voltage connecting line is connected to one or more voltage supply lines, and is connected to the first electrode of the third transistor. The inventors of the present disclosure discover that, in the related array substrates, there is a relatively large parasitic capacitance between the voltage connecting line (e.g., in the first signal line layer) and the respective light emitting control signal line in the first gate metal layer, adversely affecting display quality.

In the present array substrate, the respective light emitting control signal line em is not in the first gate metal layer, but in the first signal line layer. The first light emitting control electrode pad emP1 and the second light emitting control electrode pad emP2 are connected to the respective light emitting control signal line em of a plurality of light emitting control signal lines. Optionally, the first light emitting control electrode pad emP1 and the second light emitting control electrode pad emP2 are in the first gate metal layer. Optionally, the respective light emitting control signal line em is in the first signal line layer. The inventors of the present disclosure discover that this unique and intricate structure results in a greatly reduced parasitic capacitance between the first gate metal layer and the first signal line layer, leading to significantly improved display quality.

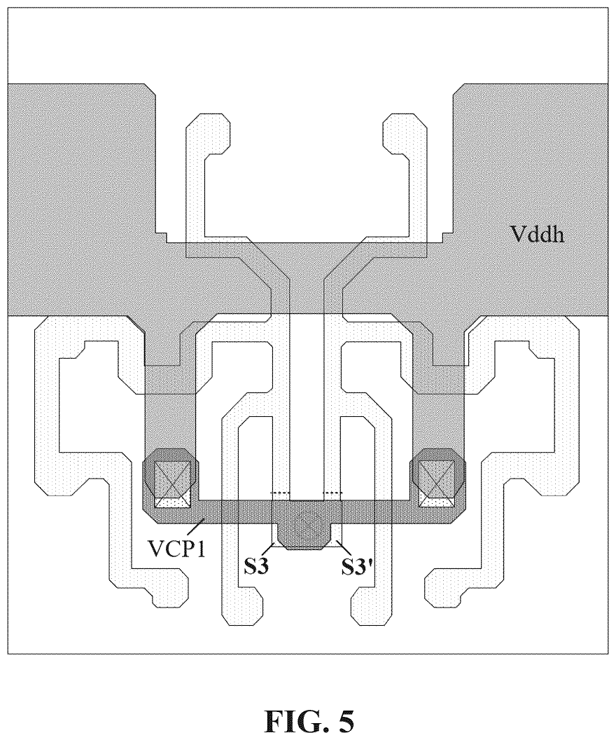

FIG. 5 illustrates a voltage supply path in an array substrate in some embodiments according to the present disclosure. Referring to FIG. 5, FIG. 3D, FIG. 3J, and FIG. 3L, in some embodiments, the array substrate includes a third transistor configured to receive a voltage supply signal; a first voltage connecting pad VCP1; and a respective first voltage supply line Vddh of a plurality of first voltage supply lines; wherein an active layer of the third transistor, the first voltage connecting pad VCP1, and the respective first voltage supply line Vddh are in three different layers. Optionally, the active layer of the third transistor is in a first semiconductor material layer; the first voltage connecting pad VCP1 is in a first signal line layer, and the respective first voltage supply line Vddh is in a second signal line layer. In some embodiments, the respective first voltage supply line Vddh is connected to the first voltage connecting pad VCP1, and the first voltage connecting pad VCP1 is connected to a first electrode S3 of the third transistor.

In some embodiments, referring to FIG. 5, FIG. 3D, FIG. 3J, and FIG. 3L, the array substrate further includes a respective light emitting control signal line em configured provide a light emitting control signal to a gate electrode of the third transistor. In some embodiments, the respective light emitting control signal line em and the first voltage connecting pad VCP1 are in a same layer.

In some embodiments, the first voltage connecting pad VCP1 is connected to first electrodes (S3 and S3′ denoted in FIG. 5) of third transistors in two adjacent pixel driving circuits in a same row.

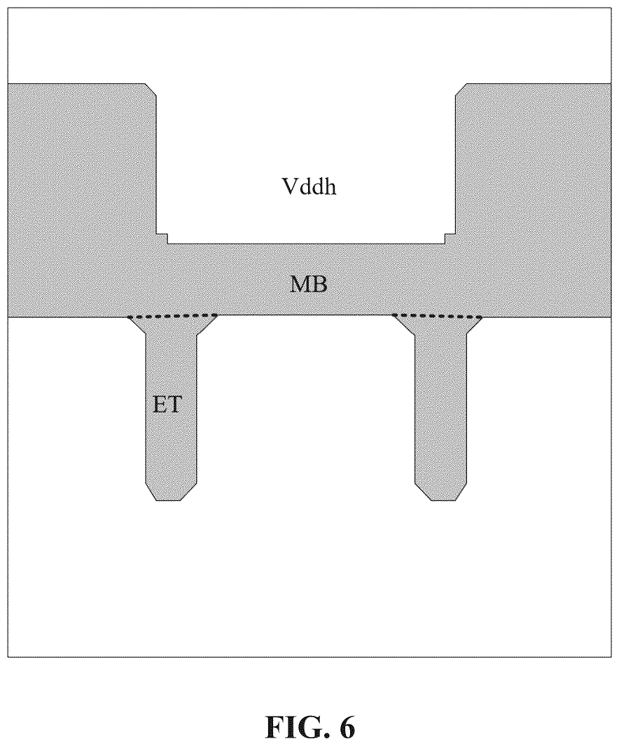

FIG. 6 is a diagram illustrating the structure of a respective first voltage supply line in an array substrate in some embodiments according to the present disclosure. Referring to FIG. 6, the respective first voltage supply line Vddh in some embodiments includes a main body MB and a plurality of extensions ET extending away from the main body MB. Optionally, the plurality of extensions ET extend away from the main body MB along a same direction. In some embodiments, a respective extension of the plurality of extensions ET is connected to the first voltage connecting pad VCP1, and the first voltage connecting pad VCP1 is connected to a first electrode S3 of the third transistor. Optionally, two adjacent extensions of the plurality of extensions ET are connected to the first voltage connecting pad VCP1, and the first voltage connecting pad VCP1 is connected to first electrodes (S3 and S3′ denoted in FIG. 5) of third transistors in two adjacent pixel driving circuits in a same row.

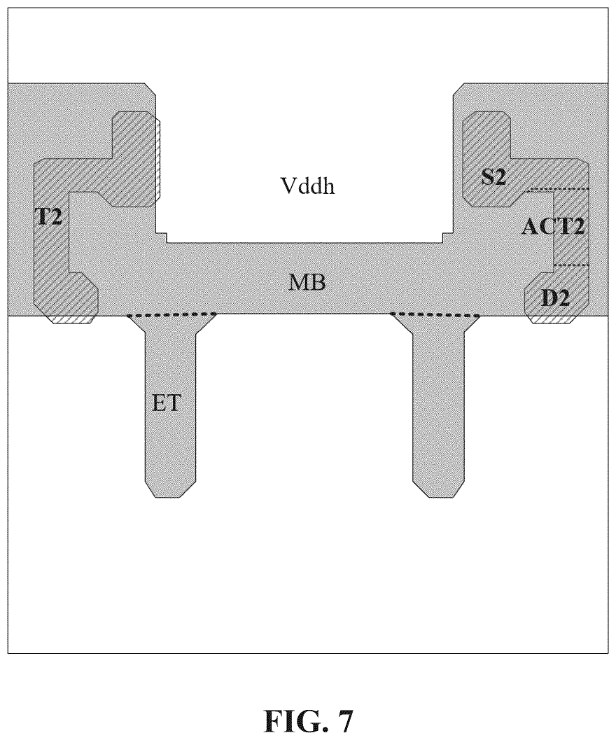

FIG. 7 is a diagram illustrating the structure of a second semiconductor material layer and a respective first voltage supply line in the array substrate depicted in FIG. 3A. Referring to FIG. 7, in some embodiments, an orthographic projection of the main body MB on a base substrate substantially covers (e.g., covers at least 80%, covers at least 85%, covers at least 90%, covers at least 95%, covers at least 99%, or completely covers) an orthographic projection of an active layer ACT2 of the second transistor T2 on the base substrate. Optionally, the orthographic projection of the main body MB on a base substrate substantially covers (e.g., covers at least 80%, covers at least 85%, covers at least 90%, covers at least 95%, covers at least 99%, or completely covers) an orthographic projection of a first electrode S2, the active layer ACT2, and a second electrode D2 of the second transistor T2 on the base substrate. The inventors of the present disclosure discover that the unique and intricate structure of the present array substrate is conducive to achieving enhancing stability of the second transistor T2.

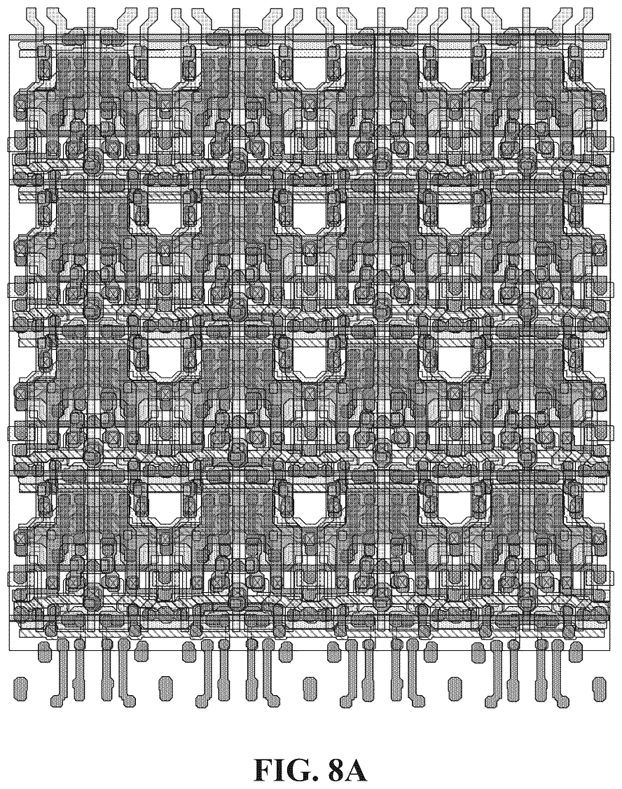

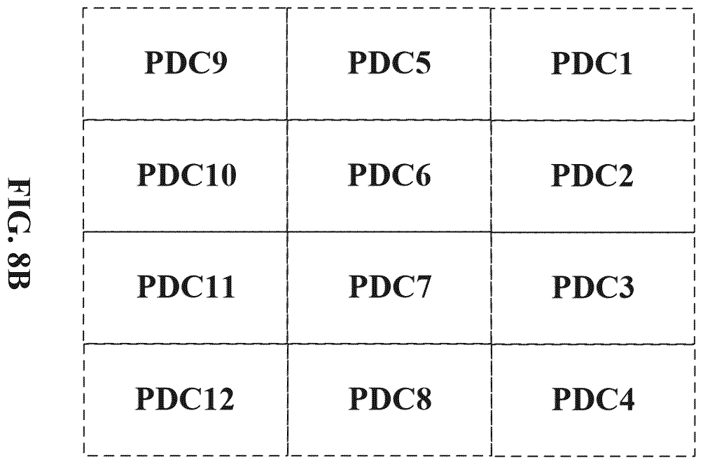

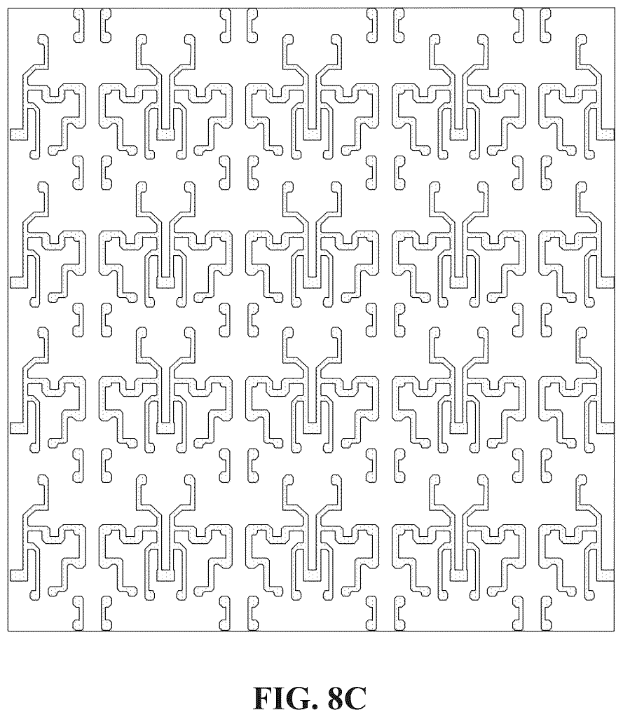

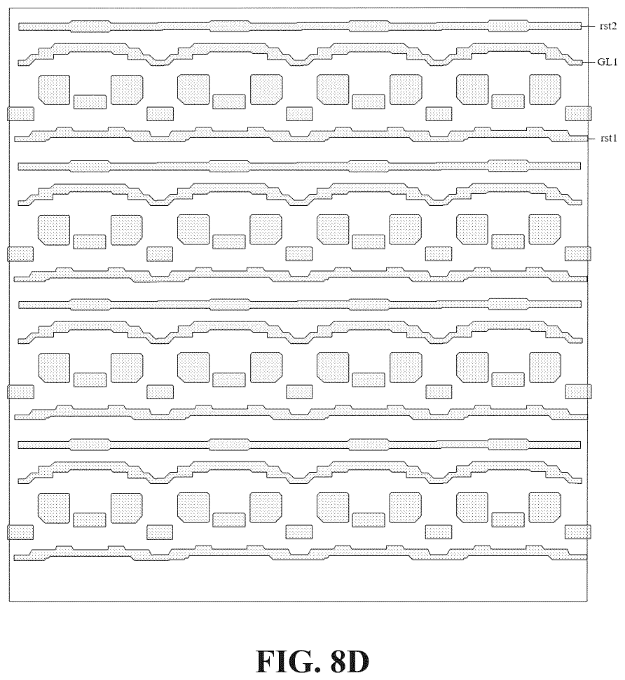

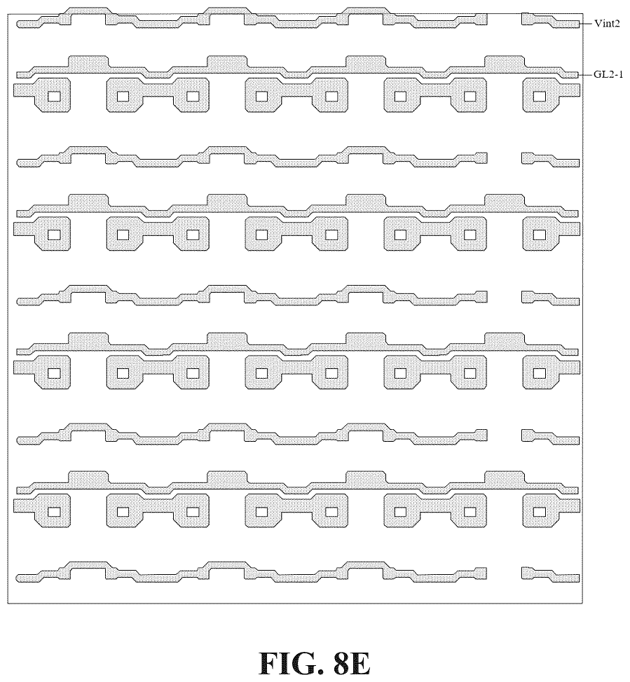

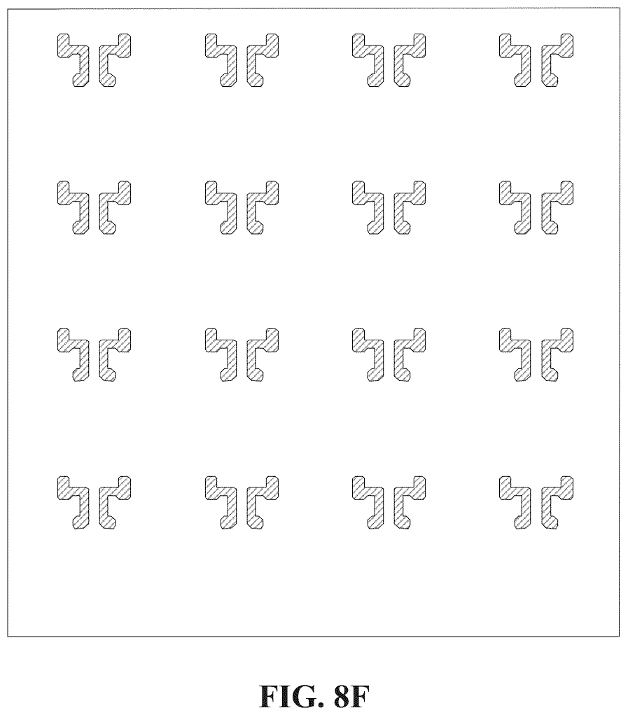

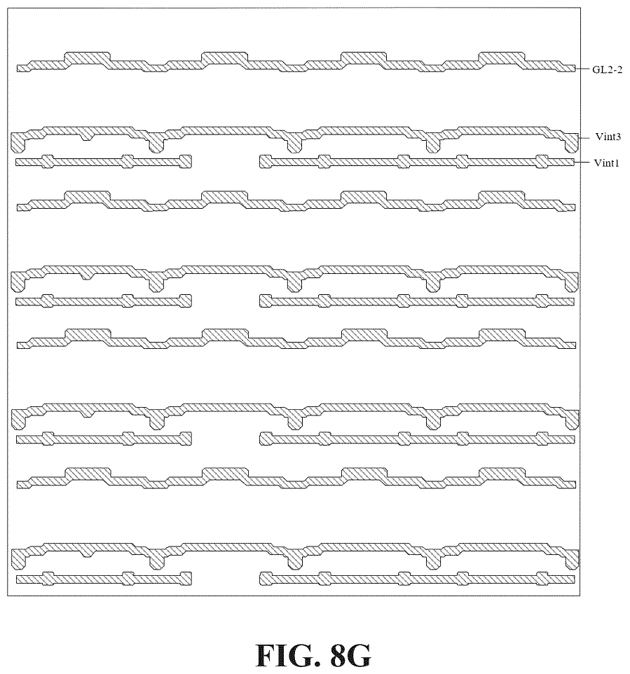

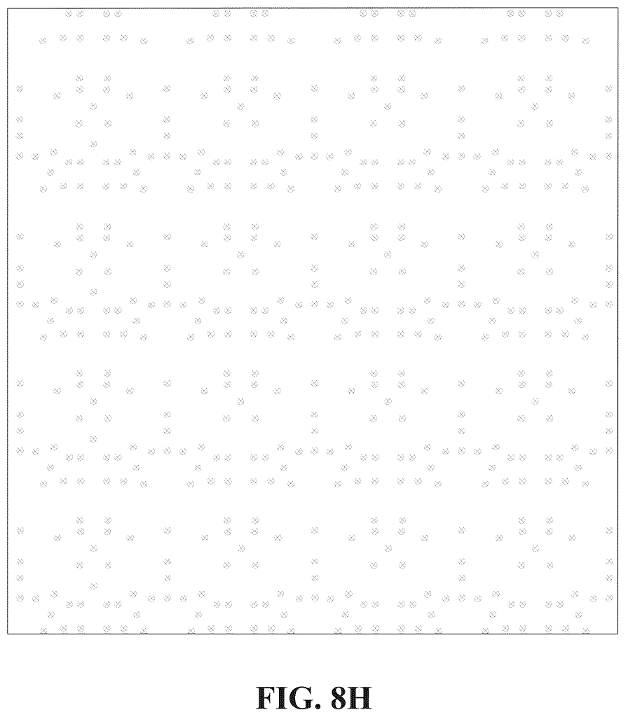

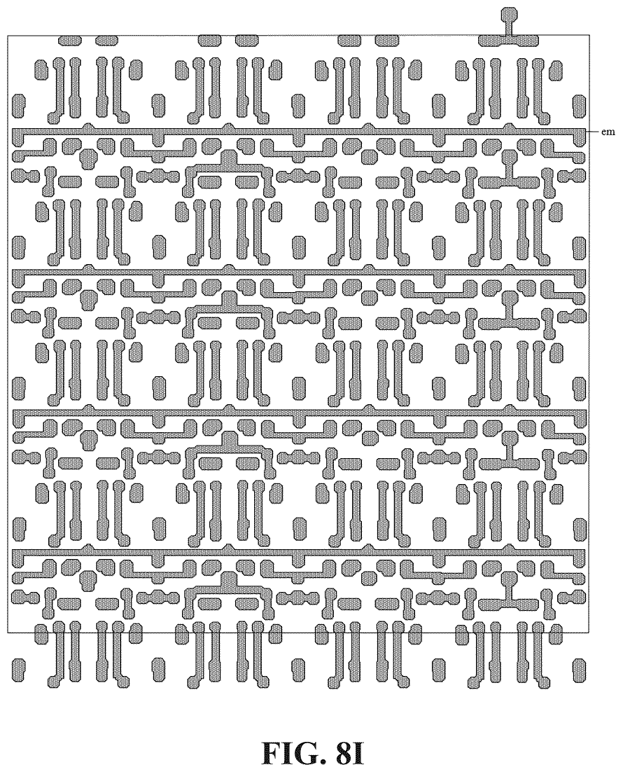

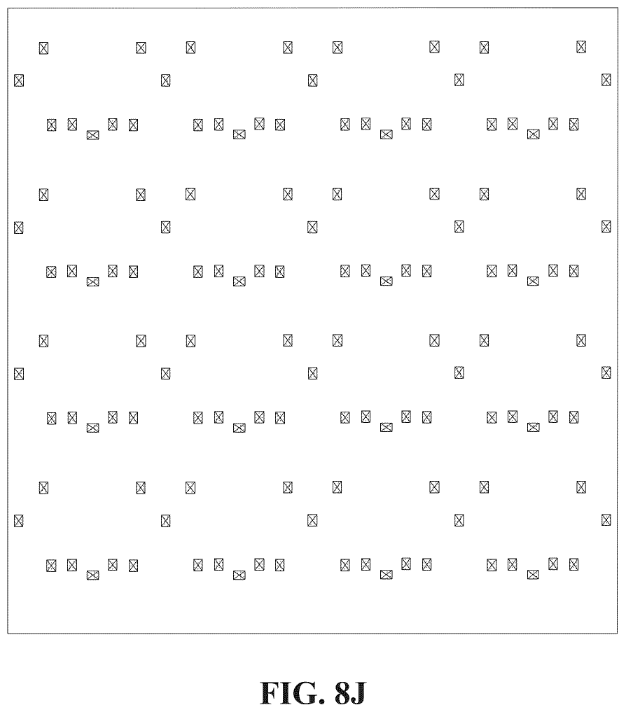

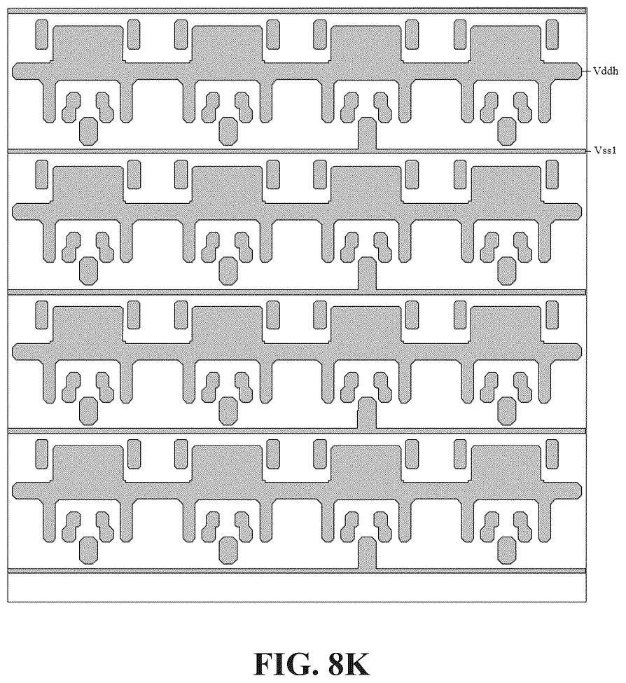

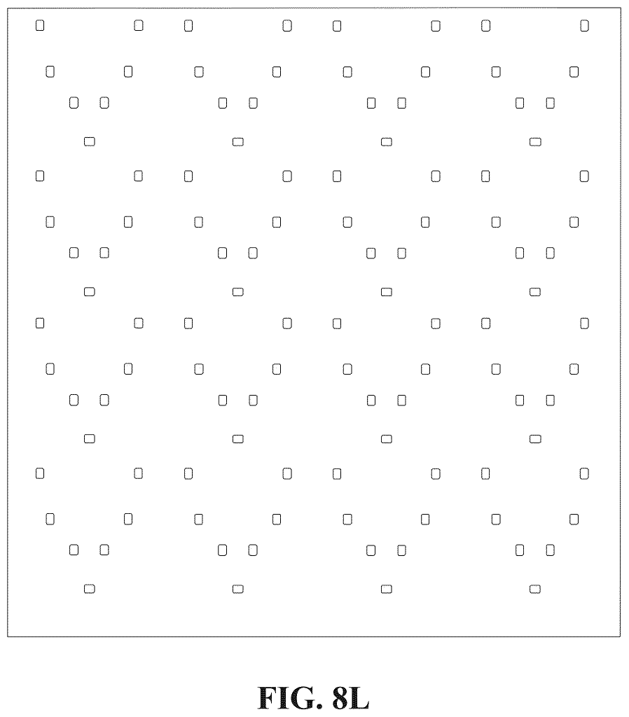

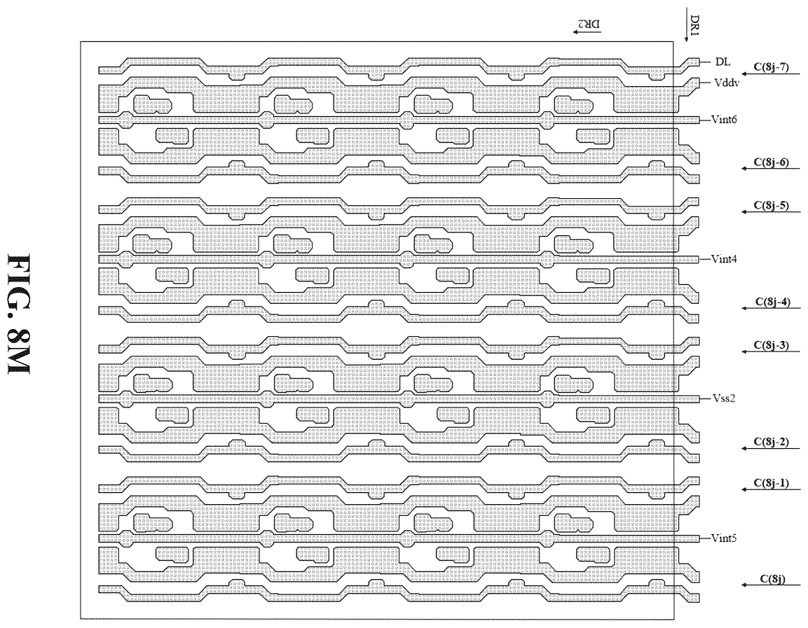

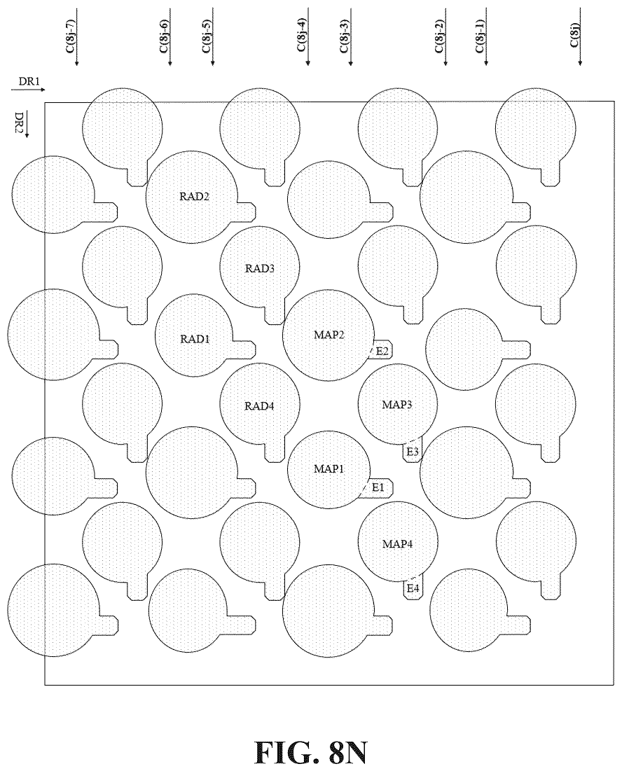

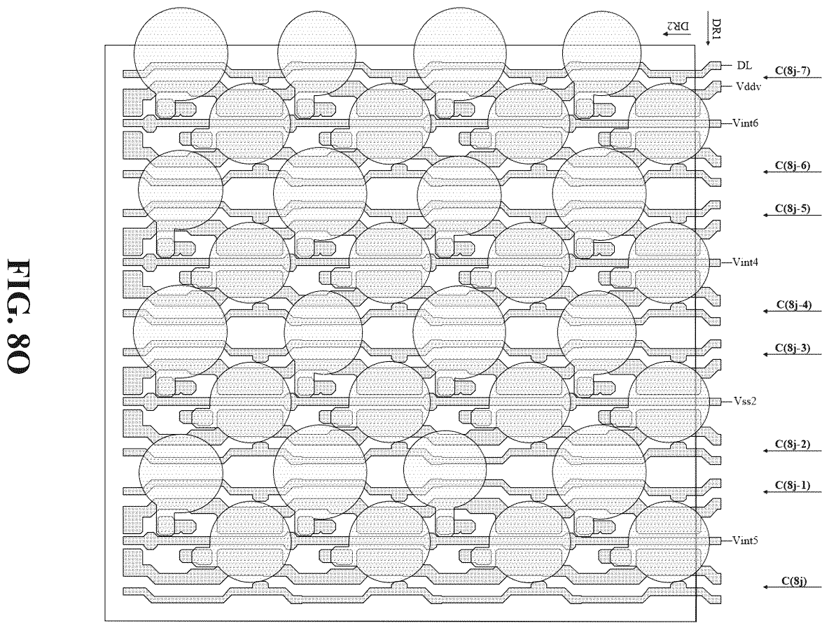

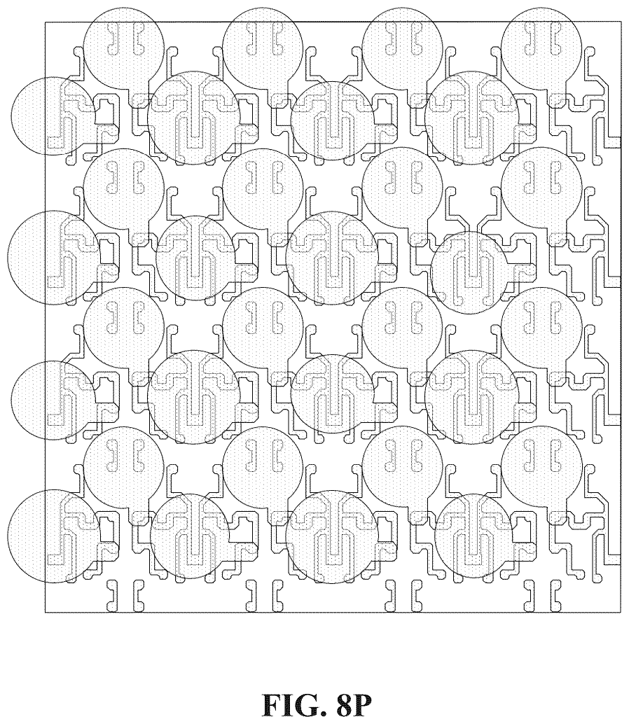

FIG. 8A is a diagram illustrating the structure of pixel driving circuits in an array substrate in some embodiments according to the present disclosure. FIG. 8B is a schematic diagram illustrating an arrangement of pixel driving circuits in the array substrate depicted in FIG. 8A. FIG. 8C is a diagram illustrating the structure of a first semiconductor material layer in the array substrate depicted in FIG. 8A. FIG. 8D is a diagram illustrating the structure of a first gate metal layer in the array substrate depicted in FIG. 8A. FIG. 8E is a diagram illustrating the structure of a second gate metal layer in the array substrate depicted in FIG. 8A. FIG. 8F is a diagram illustrating the structure of a second semiconductor material layer in the array substrate depicted in FIG. 8A. FIG. 8G is a diagram illustrating the structure of a third gate metal layer in the array substrate depicted in FIG. 8A. FIG. 8H is a diagram illustrating the structure of a passivation layer in the array substrate depicted in FIG. 8A. FIG. 8I is a diagram illustrating the structure of a first signal line layer in the array substrate depicted in FIG. 8A. FIG. 8J is a diagram illustrating the structure of a first planarization layer in the array substrate depicted in FIG. 8A. FIG. 8K is a diagram illustrating the structure of a second signal line layer in the array substrate depicted in FIG. 8A. FIG. 8L is a diagram illustrating the structure of a second planarization layer in the array substrate depicted in FIG. 8A. FIG. 8M is a diagram illustrating the structure of a third signal line layer in the array substrate depicted in FIG. 8A. FIG. 8N is a diagram illustrating the structure of an anode layer in the array substrate depicted in FIG. 8A. FIG. 8A to FIG. 8N depict a portion of the array substrate having twelve adjacent pixel driving circuits, including PDC1, PDC2, PDC3, PDC4, PDC5, PDC6, PDC7, PDC8, PDC9, PDC10, PDC11, and PDC12. PDC1 and PDC2 depicted in FIG. 8B correspond to PDC1 and PDC2 depicted in FIG. 3C.

Referring to FIG. 8A to FIG. 8N, in some embodiments, the array substrate includes pixel driving circuits arranged in J number of columns, J being a positive integer. The array substrate includes a plurality of fourth reset signal lines (e.g., a respective fourth reset signal line Vint4), a plurality of fifth reset signal lines (e.g., a respective fifth reset signal line Vint5), a plurality of sixth reset signal lines (e.g., a respective sixth reset signal line Vint6), and a plurality of second low voltage supply lines (e.g., a respective second low voltage supply line Vss2). In some embodiments, the J number of columns include a (8j-7)-th column C(8j-7) of the J columns, a (8j-6)-th column C(8j-6) of the J columns, a (8j-5)-th column C(8j-5) of the J columns, a (8j-4)-th column C(8j-4) of the J columns, a (8j-3)-th column C(8j-3) of the J columns, a (8j-2)-th column C(8j-2) of the J columns, a (8j-1)-th column C(8j-1) of the J columns, and a (8j)-th column C(8j) of J columns, J and j being positive integers, 1≤j≤(J/8).

In some embodiments, one of the respective fourth reset signal line Vint4, the respective fifth reset signal line Vint5, the respective sixth reset signal line Vint6, and the respective second low voltage supply line Vss2 is between the (8j-7)-th column C(8j-7) of the J columns and the (8j-6)-th column C(8j-6) of the J columns; another of the respective fourth reset signal line Vint4, the respective fifth reset signal line Vint5, the respective sixth reset signal line Vint6, and the respective second low voltage supply line Vss2 is between the (8j-5)-th column C(8j-5) of the J columns and (8j-4)-th column C(8j-4) of the J columns; another of the respective fourth reset signal line Vint4, the respective fifth reset signal line Vint5, the respective sixth reset signal line Vint6, and the respective second low voltage supply line Vss2 is between the (8j-3)-th column C(8j-3) of the J columns and (8j-2)-th column C(8j-2) of the J columns; and another of the respective fourth reset signal line Vint4, the respective fifth reset signal line Vint5, the respective sixth reset signal line Vint6, and the respective second low voltage supply line Vss2 is between the (8j-1)-th column C(8j-1) of the J columns and the (8j)-th column C(8j) of J columns.

In one example as depicted in FIG. 8A to FIG. 8N, the respective sixth reset signal line Vint6 is between the (8j-7)-th column C(8j-7) of the J columns and the (8j-6)-th column C(8j-6) of the J columns; the respective fourth reset signal line Vint4 is between the (8j-5)-th column C(8j-5) of the J columns and (8j-4)-th column C(8j-4) of the J columns; the respective second low voltage supply line Vss2 is between the (8j-3)-th column C(8j-3) of the J columns and (8j-2)-th column C(8j-2) of the J columns; and the respective fifth reset signal line Vint5 is between the (8j-1)-th column C(8j-1) of the J columns and the (8j)-th column C(8j) of J columns. The respective sixth reset signal line Vint6, the respective fourth reset signal line Vint4, the respective second low voltage supply line Vss2, and the respective fifth reset signal line Vint5 are sequentially arranged.

As used herein, the terms “(8j-7)-th column”, “(8j-6)-th column”, “(8j-5)-th column”, “(8j-4)-th column”, “(8j-3)-th column”, “(8j-2)-th column”, “(8j-1)-th column”, and “(8j)-th column” are used in the context of the J columns. The array substrate may or may not include additional column(s) before the first column of the J columns and/or additional columns after the last column of the J columns. In the context of the array substrate, the terms “(8j-7)-th column”, “(8j-5)-th column”, “(8j-3)-th column”, and “(8j-1)-th column” does not necessarily denote an odd-numbered column, and the term “(8j-6)-th column”, “(8j-4)-th column”, “(8j-2)-th column” and “(8j)-th column does not necessarily denote an even-numbered column. In one example, the (8j-7)-th column is an odd-numbered column in the context of the J columns, but may be an even-numbered column in the context of the array substrate. In another example, the (8j-7)-th column is an odd-numbered column in the context of the J columns, and also an odd-numbered column in the context of the array substrate. In one example, the (8j-6)-th column is an even-numbered column in the context of the J columns, but may be an odd-numbered column in the context of the array substrate. In another example, the (8j-6)-th column is an even-numbered column in the context of the J columns, and also an even-numbered column in the context of the array substrate. In one example, the (8j-5)-th column is an odd-numbered column in the context of the J columns, but may be an even-numbered column in the context of the array substrate. In another example, the (8j-5)-th column is an odd-numbered column in the context of the J columns, and also an odd-numbered column in the context of the array substrate. In one example, the (8j-4)-th column is an even-numbered column in the context of the J columns, but may be an odd-numbered column in the context of the array substrate. In another example, the (8j-4)-th column is an even-numbered column in the context of the J columns, and also an even-numbered column in the context of the array substrate. In one example, the (8j-3)-th column is an odd-numbered column in the context of the J columns, but may be an even-numbered column in the context of the array substrate. In another example, the (8j-3)-th column is an odd-numbered column in the context of the J columns, and also an odd-numbered column in the context of the array substrate. In one example, the (8j-2)-th column is an even-numbered column in the context of the J columns, but may be an odd-numbered column in the context of the array substrate. In another example, the (8j-2)-th column is an even-numbered column in the context of the J columns, and also an even-numbered column in the context of the array substrate. In one example, the (8j-1)-th column is an odd-numbered column in the context of the J columns, but may be an even-numbered column in the context of the array substrate. In another example, the (8j-1)-th column is an odd-numbered column in the context of the J columns, and also an odd-numbered column in the context of the array substrate. In one example, the (8j)-th column is an even-numbered column in the context of the J columns, but may be an odd-numbered column in the context of the array substrate. In another example, the (8j)-th column is an even-numbered column in the context of the J columns, and also an even-numbered column in the context of the array substrate.

Referring to FIG. 8N, in some embodiments, the anode layer in some embodiments includes a first respective anode RAD1, a second respective anode RAD2, a third respective anode RAD3, and a fourth respective anode RAD4. In one example, the first respective anode RAD1 is an anode for a subpixel of a first color (e.g., a red subpixel), the second respective anode RAD2 is an anode for a subpixel of a second color (e.g., a blue subpixel), and the third respective anode RAD3 and the fourth respective anode RAD4 are anodes for two subpixels of a third color (e.g., two green subpixels). In some embodiments, an array of the plurality of subpixels in the array substrate includes a R-G-B-G format repeating array, in which R stands for the red subpixel, B stands for the blue subpixel, and G stands for the green subpixel.

In some embodiments, the first respective anode RAD1 includes a first main anode part MAP1 and a first extension E1 extending away from the first main anode part MAP1. The first extension E1 connects the first main anode part MAP1 with a first corresponding anode connecting pad. In some embodiments, the second respective anode RAD2 includes a second main anode part MAP2 and a second extension E2 extending away from the second main anode part MAP2. The second extension E2 connects the second main anode part MAP2 with a second corresponding anode connecting pad. In some embodiments, the third respective anode RAD3 includes a third main anode part MAP3 and a third extension E3 extending away from the third main anode part MAP3. The third extension E3 connects the third main anode part MAP3 with a third corresponding anode connecting pad. In some embodiments, the fourth respective anode RAD4 includes a fourth main anode part MAP4 and a fourth extension E4 extending away from the fourth main anode part MAP4. The fourth extension E4 connects the fourth main anode part MAP4 with a fourth corresponding anode connecting pad. Optionally, the first extension E1 extends away from the first main anode part MAP1 along a direction substantially parallel to the first direction DR1. Optionally, the second extension E2 extends away from the second main anode part MAP2 along a direction substantially parallel to the first direction DR1. Optionally, the third extension E3 extends away from the third main anode part MAP3 along a direction substantially parallel to the second direction DR2. Optionally, the fourth extension E4 extends away from the fourth main anode part MAP4 along a direction substantially parallel to the second direction DR2.

FIG. 8O is a diagram illustrating the structure of a third signal line layer and an anode layer in the array substrate depicted in FIG. 8A. In some embodiments, referring to FIG. 8M, FIG. 8N, and FIG. 8O, an orthographic projection of the first main anode part MAP1 on a base substrate at least partially overlaps with an orthographic projection of two adjacent data lines of the plurality of data lines on the base substrate. Optionally, the orthographic projection of the first main anode part MAP1 on a base substrate at least partially overlaps with an orthographic projection of two adjacent second voltage supply lines of the plurality of second voltage supply lines on the base substrate. In some embodiments, an orthographic projection of the second main anode part MAP2 on a base substrate at least partially overlaps with an orthographic projection of two adjacent data lines of the plurality of data lines on the base substrate.

Optionally, the orthographic projection of the second main anode part MAP2 on a base substrate at least partially overlaps with an orthographic projection of two adjacent second voltage supply lines of the plurality of second voltage supply lines on the base substrate.

Optionally, the two adjacent data lines are configured to provide data signals to pixel driving circuits in a (8j-k1)-th column and a (8j-(k1+1))-th column, wherein J is a positive integer, 1≤j≤(J/8), k1 is a positive integer, and 1≤k1<j. Optionally, the two adjacent second voltage supply lines are configured to provide voltage supply signals to pixel driving circuits in a (8j-k1)-th column and a (8j-(k1+1))-th column, wherein J is a positive integer, 1≤j≤(J/8), k1 is an odd positive integer, and 1≤k1<j. Examples of the (8j-k1)-th column and the (8j-(k1+1))-th column include the (8j-1)-th column C(8j-1) and the (8j-2)-th column C(8j-2), the (8j-3)-th column C(8j-3) and the (8j-4)-th column C(8j-4), the (8j-5)-th column C(8j-5) and the (8j-6)-th column C(8j-6).

In some embodiments, an orthographic projection of the first main anode part MAP1 on a base substrate is completely non-overlapping with an orthographic projection of the plurality of fourth reset signal lines on the base substrate, completely non-overlapping with an orthographic projection of the plurality of fifth reset signal lines on the base substrate, completely non-overlapping with an orthographic projection of the plurality of sixth reset signal lines on the base substrate, and completely non-overlapping with an orthographic projection of the plurality of second low voltage supply lines on the base substrate. In some embodiments, an orthographic projection of the second main anode part MAP2 on a base substrate is completely non-overlapping with an orthographic projection of the plurality of fourth reset signal lines on the base substrate, completely non-overlapping with an orthographic projection of the plurality of fifth reset signal lines on the base substrate, completely non-overlapping with an orthographic projection of the plurality of sixth reset signal lines on the base substrate, and completely non-overlapping with an orthographic projection of the plurality of second low voltage supply lines on the base substrate.

In some embodiments, an orthographic projection of the third main anode part MAP3 on a base substrate at least partially overlaps with an orthographic projection of two adjacent second voltage supply lines of the plurality of second voltage supply lines on the base substrate, and at least partially overlaps with an orthographic projection of one of a respective fourth reset signal line Vint4, a respective fifth reset signal line Vint5, a respective sixth reset signal line Vint6, and a respective second low voltage supply line Vss2 on the base substrate.

In some embodiments, an orthographic projection of the fourth main anode part MAP4 on a base substrate at least partially overlaps with an orthographic projection of two adjacent second voltage supply lines of the plurality of second voltage supply lines on the base substrate, and at least partially overlaps with an orthographic projection of one of a respective fourth reset signal line Vint4, a respective fifth reset signal line Vint5, a respective sixth reset signal line Vint6, and a respective second low voltage supply line Vss2 on the base substrate. Optionally, the two adjacent second voltage supply lines are configured to provide voltage supply signals to pixel driving circuits in a (8j-k2)-th column and a (8j-(k2+1))-th column, wherein J is a positive integer, 1≤j≤(J/8), k2 is zero or an even positive integer, and 0≤k2<j. Examples of the (8j-k2)-th column and the (8j-(k2+1))-th column include the (8j)-th column C(8j) and the (8j-1)-th column C(8j-1), the (8j-2)-th column C(8j-2) and the (8j-3)-th column C(8j-3), the (8j-4)-th column C(8j-4) and the (8j-5)-th column C(8j-5), the (8j-6)-th column C(8j-6) and the (8j-7)-th column C(8j-7).

FIG. 8P is a diagram illustrating the structure of a first semiconductor material layer and an anode layer in the array substrate depicted in FIG. 8A. Referring to FIG. 8C, FIG. 8N, FIG. 8P, FIG. 3D, and FIG. 3O, an orthographic projection of the first main anode part MAP1 on a base substrate at least partially overlaps with orthographic projections of active layers of third reset transistors in two adjacent columns of pixel driving circuits. Optionally, the two adjacent columns of pixel driving circuits include a (8j-k1)-th column and a (8j-(k1+1))-th column, wherein J is a positive integer, 1≤j≤(J/8), k1 is a positive integer, and 1≤k1<j. Examples of the (8j-k1)-th column and the (8j-(k1+1))-th column include the (8j-1)-th column C(8j-1) and the (8j-2)-th column C(8j-2), the (8j-3)-th column C(8j-3) and the (8j-4)-th column C(8j-4), the (8j-5)-th column C(8j-5) and the (8j-6)-th column C(8j-6).

In some embodiments, an orthographic projection of at least one of the first respective anode RAD1, the second respective anode RAD2, the third respective anode RAD3, or the fourth respective anode RAD4 on the base substrate at least partially overlaps with an orthographic projection of the second electrode Dr3 of the third reset transistor Tr3 on the base substrate.

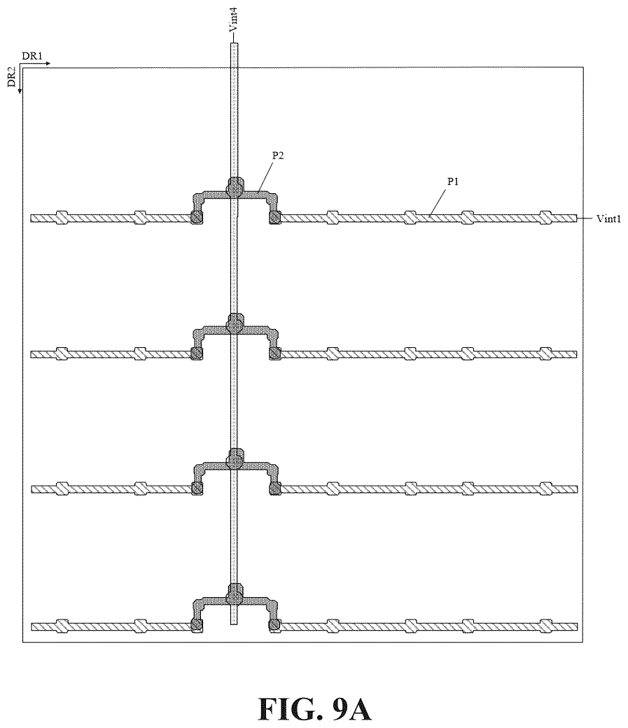

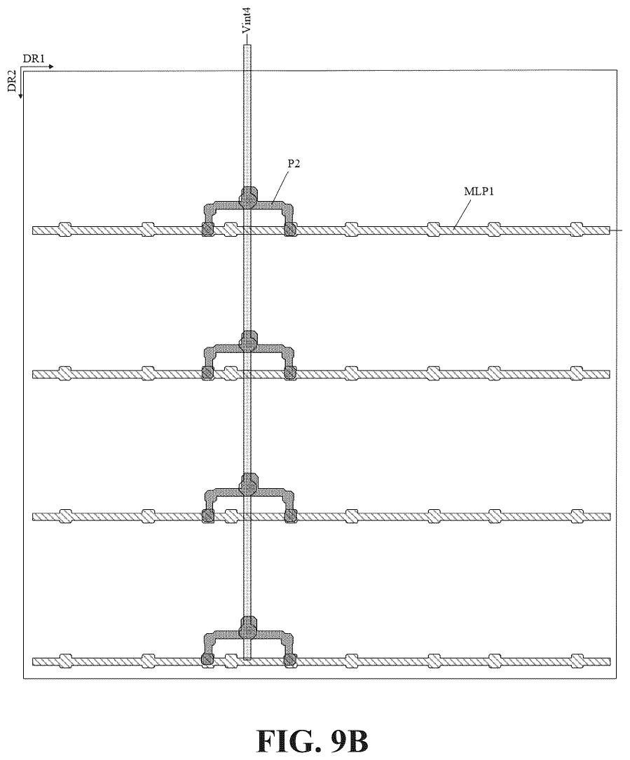

FIG. 9A illustrates a first interconnected reset signal network in some embodiments according to the present disclosure. Referring to FIG. 9A, the array substrate in some embodiments includes a first interconnected reset signal network configured to provide a first reset signal to a plurality of pixel driving circuits. For example, the first interconnected reset signal network is configured to provide the first reset signal to first electrodes of first reset transistors in the plurality of pixel driving circuits. In some embodiments, the first interconnected reset signal network includes a plurality of first reset signal lines extending along a direction substantially parallel to a first direction DR1, respectively; and a plurality of fourth reset signal lines extending along a direction substantially parallel to a second direction DR2; wherein the plurality of first reset signal lines respectively cross over the plurality of fourth reset signal lines. As used herein, the term “substantially parallel” means that an angle is in the range of 0 degree to approximately 45 degrees, e.g., 0 degree to approximately 5 degrees, 0 degree to approximately 10 degrees, 0 degree to approximately 15 degrees, 0 degree to approximately 20 degrees, 0 degree to approximately 25 degrees, 0 degree to approximately 30 degrees.

Optionally, a respective first reset signal line Vint1 of the plurality of first reset signal lines is connected to at least multiple ones of the plurality of fourth reset signal lines; and a respective fourth reset signal line Vint4 of the plurality of fourth reset signal lines is connected to at least multiple ones of the plurality of first reset signal lines.

In some embodiments, the respective first reset signal line Vint1 includes multiple first portions P1 and multiple second portions P2 alternately arranged. Two adjacent second portions of the multiple second portions P2 are connected by a first portion of the multiple first portions P1. Two adjacent first portions of the multiple first portions P1 are connected by a second portion of the multiple second portions P2. A respective second portion of the multiple second portions P2 is connected to the respective fourth reset signal line Vint4.

In some embodiments, the multiple first portions P1, the multiple second portions P2, and the respective fourth reset signal line Vint4 are in three different layers, respectively. In one particular example, the multiple first portions P1 are in the third gate metal layer, the multiple second portions P2 are in the first signal line layer, and the respective fourth reset signal line Vint4 is in the third signal line layer. The inventors of the present disclosure discover that the unique and intricate structure of the first interconnected reset signal network optimizes the layout of the signal lines in the array substrate.

FIG. 9B illustrates a first interconnected reset signal network in some embodiments according to the present disclosure. Referring to FIG. 9B, the respective first reset signal line Vint1 includes a first main line portion MLP1 and multiple second portions P2. The first main line portion MLP1 is a continuous line portion connected to the multiple second portions P2. A respective second portion of the multiple second portions P2 is connected to the respective fourth reset signal line Vint4.

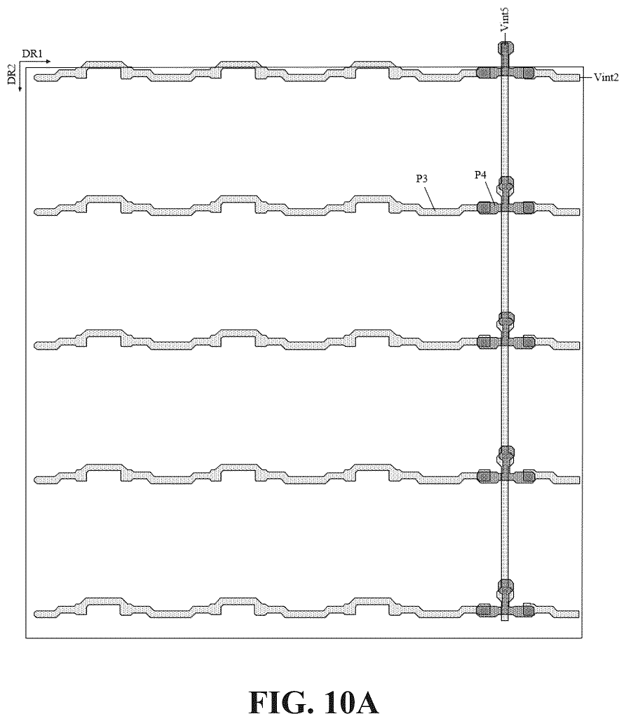

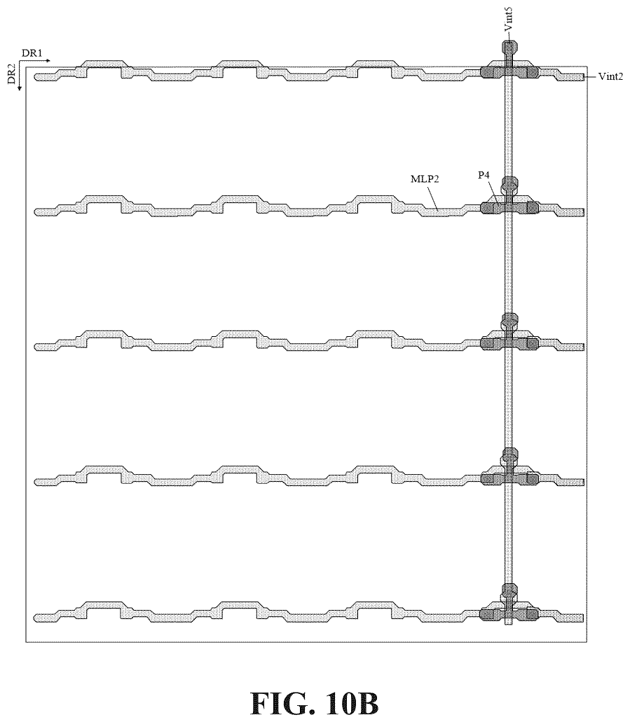

FIG. 10A illustrates a second interconnected reset signal network in some embodiments according to the present disclosure. Referring to FIG. 10A, the array substrate in some embodiments includes a second interconnected reset signal network configured to provide a second reset signal to a plurality of pixel driving circuits. For example, the second interconnected reset signal network is configured to provide the second reset signal to first electrodes of second reset transistors in the plurality of pixel driving circuits. In some embodiments, the second interconnected reset signal network includes a plurality of second reset signal lines extending along a direction substantially parallel to a first direction DR1, respectively; and a plurality of fifth reset signal lines extending along a direction substantially parallel to a second direction DR2, respectively; wherein the plurality of second reset signal lines respectively cross over the plurality of fifth reset signal lines.

Optionally, a respective second reset signal line Vint2 of the plurality of second reset signal lines is connected to at least multiple ones of the plurality of fifth reset signal lines; and a respective fifth reset signal line Vint5 of the plurality of fifth reset signal lines is connected to at least multiple ones of the plurality of second reset signal lines.

In some embodiments, the respective second reset signal line Vint2 includes multiple third portions P3 and multiple fourth portions P4 alternately arranged. Two adjacent fourth portions of the multiple fourth portions P4 are connected by a third portion of the multiple third portions P3. Two adjacent third portions of the multiple third portions P3 are connected by a fourth portion of the multiple fourth portions P4. A respective fourth portion of the multiple fourth portions P4 is connected to the respective fifth reset signal line Vint5.

In some embodiments, the multiple third portions P3, the multiple fourth portions P4, and the respective fifth reset signal line Vint5 are in three different layers, respectively. In one particular example, the multiple third portions P3 are in the second gate metal layer, the multiple fourth portions P4 are in the first signal line layer, and the respective fifth reset signal line Vint5 is in the third signal line layer. The inventors of the present disclosure discover that the unique and intricate structure of the second interconnected reset signal network optimizes the layout of the signal lines in the array substrate.

FIG. 10B illustrates a second interconnected reset signal network in some embodiments according to the present disclosure. Referring to FIG. 10B, the respective second reset signal line Vint2 includes a second main line portion MLP2 and multiple fourth portions P4. The second main line portion MLP2 is a continuous line portion connected to the multiple fourth portions P4. A respective fourth portion of the multiple fourth portions P4 is connected to the respective fifth reset signal line Vint5.

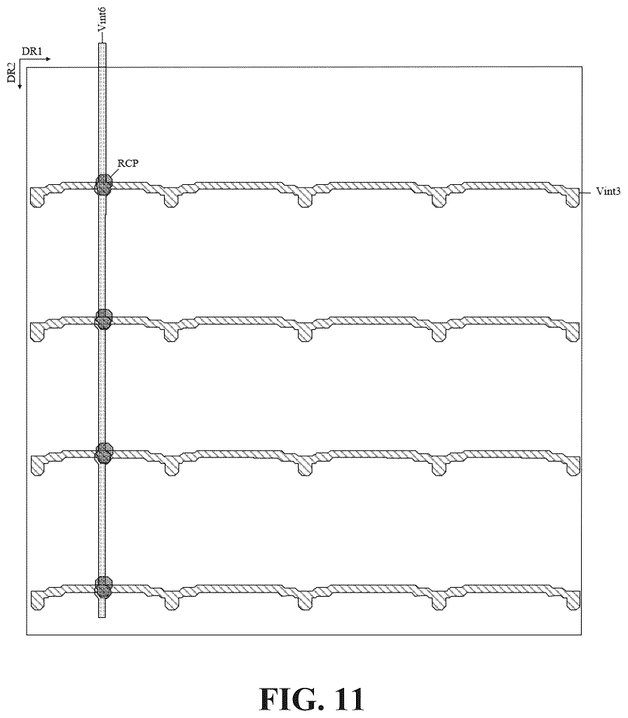

FIG. 11 illustrates a third interconnected reset signal network in some embodiments according to the present disclosure. Referring to FIG. 11, the array substrate in some embodiments includes a third interconnected reset signal network configured to provide a third reset signal to a plurality of pixel driving circuits. For example, the third interconnected reset signal network is configured to provide the third reset signal to first electrodes of third reset transistors in the plurality of pixel driving circuits. In some embodiments, the third interconnected reset signal network includes a plurality of third reset signal lines extending along a direction substantially parallel to a first direction DR1, respectively; and a plurality of sixth reset signal lines extending along a direction substantially parallel to a second direction DR2, respectively; wherein the plurality of third reset signal lines respectively cross over the plurality of sixth reset signal lines.

Optionally, a respective third reset signal line Vint3 of the plurality of third reset signal lines is connected to at least multiple ones of the plurality of sixth reset signal lines; and a respective sixth reset signal line Vint6 of the plurality of sixth reset signal lines is connected to at least multiple ones of the plurality of third reset signal lines.

In some embodiments, the array substrate further includes a plurality of reset connecting pads. A respective reset connecting pad RCP is connected to an individual third reset signal line of the plurality of third reset signal lines, and is connected to an individual sixth reset signal line of the plurality of sixth reset signal lines.

In some embodiments, the respective third reset signal line Vint3, the respective sixth reset signal line Vint6, and the respective reset connecting pad RCP are in three different layers, respectively. In one particular example, the respective third reset signal line Vint3 is in the third gate metal layer, the respective reset connecting pad RCP is in the first signal line layer, and the respective sixth reset signal line Vint6 is in the third signal line layer.

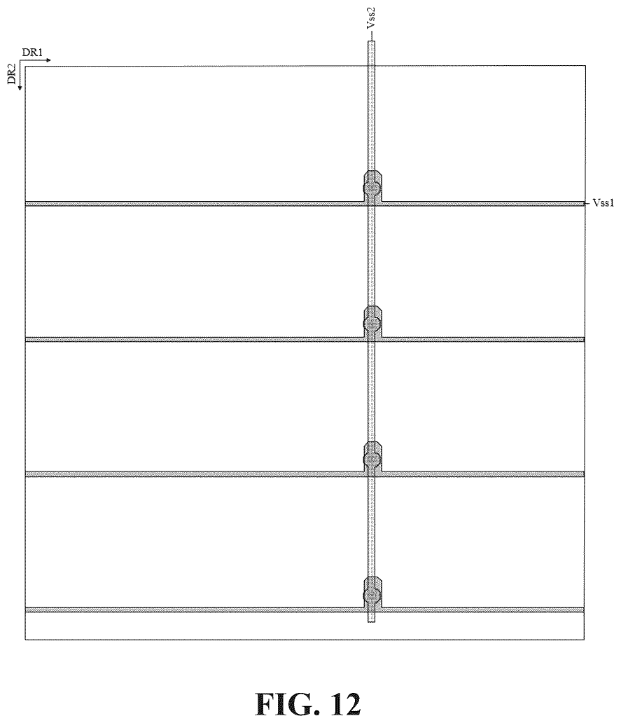

FIG. 12 illustrates an interconnected low voltage supply network in some embodiments according to the present disclosure. Referring to FIG. 12, the array substrate in some embodiments includes an interconnected low voltage supply network configured to provide a low voltage supply signal to a plurality of pixel driving circuits. For example, the interconnected low voltage supply network is configured to provide the low voltage supply signal to the cathode in the plurality of pixel driving circuits. In some embodiments, the interconnected low voltage supply network includes a plurality of first low voltage supply lines extending along a direction substantially parallel to a first direction DR1, respectively; and a plurality of second low voltage supply lines extending along a direction substantially parallel to a second direction DR2, respectively; wherein the plurality of first low voltage supply lines respectively cross over the plurality of second low voltage supply lines.

Optionally, a respective first low voltage supply line Vss1 of the plurality of first low voltage supply lines is connected to at least multiple ones of the plurality of second low voltage supply lines; and a respective second low voltage supply line Vss2 of the plurality of second low voltage supply lines is connected to at least multiple ones of the plurality of first low voltage supply lines.

In some embodiments, the respective first low voltage supply line Vss1 and the respective second low voltage supply line Vss2 are in two different layers, respectively. In one particular example, the respective first low voltage supply line Vss1 is in the second signal line layer, and the respective second low voltage supply line Vss2 is in the third signal line layer.

In related array substrates, reset signal lines along the second direction are typically in the first signal line layer, which is close to the first gate metal layer. The proximity of the reset signal lines along the second direction and the gate lines in the first gate metal layer results in a relatively large parasitic capacitance, which in turn leads to an increase loading in the gate lines. The increased loading in the gate lines demands an increased driving load for gate scan circuit (e.g., a gate-on-array circuit). The inventors of the present disclosure discover that, by having the reset signal lines along the second direction in the third signal line layer, which is spaced apart from the first gate metal layer by several layers, the demand on the driving load for the gate scan circuit can be reduced.

In some embodiments, the array substrate includes a plurality of first gate lines configured to provide gate scanning signals to gate electrodes of first transistors in a plurality of pixel driving circuits; a plurality of first voltage supply lines on a side of the plurality of first gate lines away from a base substrate, the plurality of first voltage supply lines configured to provide a voltage supply signal to first electrodes of third transistors and fourth transistors in the plurality of pixel driving circuits; and a plurality of fourth rest signal lines, a plurality of fifth reset signal lines, or a plurality of sixth reset signal lines on a side of the plurality of first voltage supply lines away from the plurality of first gate lines. The plurality of fourth rest signal lines, the plurality of fifth reset signal lines, or the plurality of sixth reset signal lines extend along the second direction.

In related array substrates, reset signal lines along the second direction (e.g., the plurality of fourth rest signal lines, the plurality of fifth reset signal lines, or the plurality of sixth reset signal lines) are alternately arranged, and the reset signal lines along the second direction are typically on a side of the plurality of first voltage supply lines closer to the plurality of first gate lines, for example, typically in the first signal line layer. The layout of the reset signal lines along the second direction in the related array substrates results in different capacitances for nodes (e.g., the node N1, the node N2, or the node N3) in different columns of pixel driving circuits, leading to display non-uniformity in the array substrate. The inventors of the present disclosure discover that, by having the reset signal lines along the second direction spaced apart from the plurality of first gate lines by the plurality of first voltage supply lines, the plurality of first voltage supply lines shield the nodes from the reset signal lines along the second direction, resulting in a significantly improved display uniformity.

In related array substrates, the plurality of light emitting control signal lines are typically in the first gate metal layer, and a respective light emitting control signal line of the plurality of light emitting control signal lines typically includes gate electrodes of the third transistor and the fourth transistor. The related array substrates typically include a second node connecting line (e.g., in the first signal line layer) connecting the second electrode D3 of the third transistor T3 to the second electrode Dr3 of the third reset transistor Tr3. The inventors of the present disclosure discover that, in the related array substrates, the presence of the second node connecting line results in a relatively large parasitic capacitance between the second node connecting line in the first signal line layer and the respective light emitting control signal line in the first gate metal layer, adversely affecting display quality. Moreover, the related array substrates require a relatively large number of vias for connecting the second node connecting line in the first signal line layer and components in the first semiconductor material layer, affecting the layout of signal lines in the related array substrates.

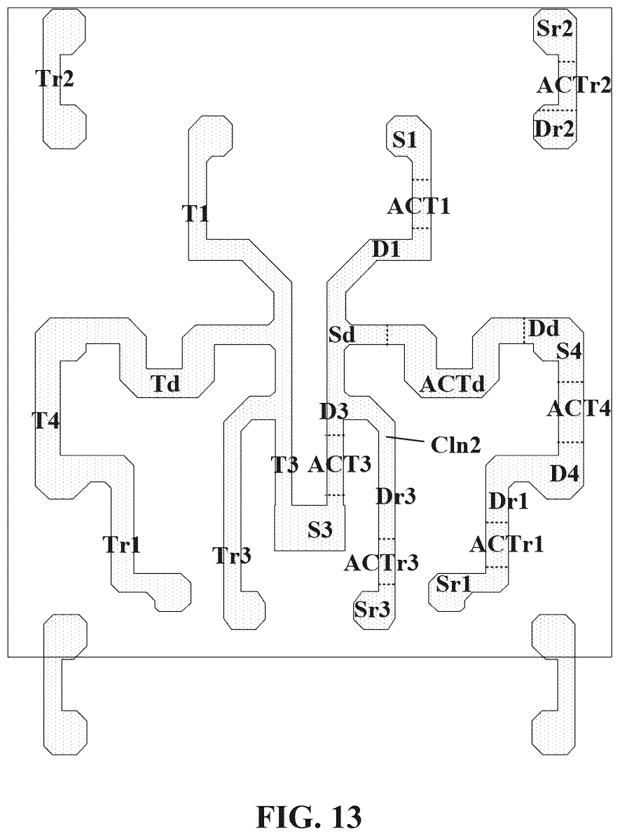

FIG. 13 is a diagram illustrating the structure of a first semiconductor material layer in the array substrate depicted in FIG. 3A. Referring to FIG. 13, in some embodiments, a respective pixel driving circuit of the plurality of pixel driving circuits comprises a second node connecting line Cln2 that is connected to a second electrode D3 of the first light emitting control transistor T3, and connected to a second electrode Dr3 of the third reset transistor Tr3. In the present array substrate, the second node connecting line Cln2 is in a same layer as active layers of the first light emitting control transistor T3 and the third reset transistor Tr3.

In some embodiments, referring to FIG. 4A and FIG. 13, the plurality of light emitting control signal lines em are spaced apart from the second node connecting line Cln2 by at least three insulating layers, e.g., three insulating layers, four insulating layers or five insulating layers. In some embodiments, the plurality of light emitting control signal lines em are spaced apart from the second node connecting line Cln2 by at least three of a gate insulating layer GI, an insulating layer IN, a first inter-layer dielectric layer ILD1, a second inter-layer dielectric layer ILD2, or a passivation layer PVX. In one example, the plurality of light emitting control signal lines em are spaced apart from the second node connecting line Cin2 by the gate insulating layer GI, the insulating layer IN, the first inter-layer dielectric layer ILD1, the second inter-layer dielectric layer ILD2, and the passivation layer PVX.

The inventors of the present disclosure discover that, by having the plurality of light emitting control signal lines em spaced apart from the second node connecting line Cln2 by at least three insulating layers, the parasitic capacitance between the second node connecting line Cln2 and the plurality of light emitting control signal lines em can be significantly reduced, achieving enhanced display quality.

In some embodiments, referring to FIG. 4A, the plurality of light emitting control signal lines em and the first node connecting line Cln1 are in a same layer. In some embodiments, referring to FIG. 4A and FIG. 13, the first node connecting line Cln1 is spaced apart from the second node connecting line Cln2 by at least three insulating layers, e.g., three insulating layers, four insulating layers or five insulating layers. In some embodiments, the first node connecting line Cln1 is spaced apart from the second node connecting line Cln2 by at least three of a gate insulating layer GI, an insulating layer IN, a first inter-layer dielectric layer ILD1, a second inter-layer dielectric layer ILD2, or a passivation layer PVX. In one example, the first node connecting line Cln1 is spaced apart from the second node connecting line Cln2 by the gate insulating layer GI, the insulating layer IN, the first inter-layer dielectric layer ILD1, the second inter-layer dielectric layer ILD2, and the passivation layer PVX.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a micro light emitting diode display apparatus. Optionally, the display apparatus is a mini light emitting diode display apparatus.

In another aspect, the present disclosure provides a method of fabricating an array substrate. In some embodiments, the method includes forming a plurality of pixel driving circuits. Optionally, forming a respective pixel driving circuit of the plurality of pixel driving circuits includes forming a driving transistor, forming a data write transistor, forming a first light emitting control transistor, and forming a third reset transistor. Optionally, active layers of the driving transistor, the data write transistor, the first light emitting control transistor, and the third reset transistor are formed in a first semiconductor material layer. Optionally, a second electrode of the data write transistor, a first electrode of the driving transistor, a second electrode of the first light emitting control transistor, and a second electrode of the third reset transistor are formed in first semiconductor material layer. Optionally, the second electrode of the data write transistor, the first electrode of the driving transistor, the second electrode of the first light emitting control transistor, and the second electrode of the third reset transistor are formed as parts of a unitary structure. Optionally, the second electrode of the data write transistor, the first electrode of the driving transistor, the second electrode of the first light emitting control transistor, and the second electrode of the third reset transistor are connected to each other by one or more portions of the first semiconductor material layer.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising a plurality of pixel driving circuits;
wherein a respective pixel driving circuit of the plurality of pixel driving circuits comprises a driving transistor, a first light emitting control transistor, and a third reset transistor;
active layers of the driving transistor, the first light emitting control transistor, and the third reset transistor are in a first semiconductor material layer;
a first electrode of the driving transistor, a second electrode of the first light emitting control transistor, and a second electrode of the third reset transistor are in the first semiconductor material layer;
the first electrode of the driving transistor, the second electrode of the first light emitting control transistor, and the second electrode of the third reset transistor are parts of a unitary structure; and
the first electrode of the driving transistor, the second electrode of the first light emitting control transistor, and the second electrode of the third reset transistor are connected to each other by one or more portions of the first semiconductor material layer.

2. The array substrate of claim 1, further comprising:
a first light emitting control electrode pad on the first semiconductor material layer; and
a plurality of light emitting control signal lines on a side of the first light emitting control electrode pad away from the first semiconductor material layer;
wherein the first light emitting control electrode pad comprises a gate electrode of the first light emitting control transistor; and
a respective light emitting control signal line of the plurality of light emitting control signal lines is connected to the first light emitting control electrode pad through a via.

3. The array substrate of claim 1, further comprising
a second light emitting control electrode pad on the first semiconductor material layer; and
a plurality of light emitting control signal lines on a side of the second light emitting control electrode pad away from the first semiconductor material layer;
wherein the respective pixel driving circuit further comprises a second light emitting control transistor;
the second light emitting control electrode pad comprises a gate electrode of the second light emitting control transistor; and
a respective light emitting control signal line of the plurality of light emitting control signal lines is connected to the second light emitting control electrode pad through a via.

4. The array substrate of claim 2, wherein the respective pixel driving circuit further comprises a storage capacitor comprising a first capacitor electrode and a second capacitor electrode;
the first light emitting control electrode pad and the first capacitor electrode are in a first gate metal layer;
the second capacitor electrode is in a second gate metal layer on a side of the first gate metal layer away from the first semiconductor material layer;
the plurality of light emitting control signal lines are in a first signal line layer on a side of the second gate metal layer away from the first gate metal layer.

5. The array substrate of claim 4, wherein the respective pixel driving circuit further comprises a compensating transistor;
an active layer of the compensating transistor is in a second semiconductor material layer on a side of the second gate metal layer away from the first gate metal layer;
at least a portion of a gate electrode of the compensating transistor is in a third gate metal layer on a side of the second semiconductor material layer away from the second gate metal layer; and
the plurality of light emitting control signal lines are in the first signal line layer on a side of the third gate metal layer away from the second semiconductor material layer.

6. The array substrate of claim 1, further comprising a first voltage connecting pad and a plurality of first voltage supply lines;
wherein an active layer of the first light emitting control transistor, the first voltage connecting pad, and the plurality of first voltage supply lines are in three different layers; and
a respective first voltage supply line of the plurality of first voltage supply lines is connected to the first voltage connecting pad, and the first voltage connecting pad is connected to a first electrode of the first light emitting control transistor.

7. The array substrate of claim 6, wherein an orthographic projection of the second electrode of the third reset transistor on a base substrate at least partially overlaps with an orthographic projection of the first voltage connecting pad on the base substrate.

8. The array substrate of claim 6, further comprising a plurality of light emitting control signal lines;
wherein a respective light emitting control signal line of the plurality of light emitting control signal lines is configured provide a light emitting control signal to a gate electrode of the first light emitting control transistor; and
the first voltage connecting pad is in a same layer as the plurality of light emitting control signal lines.

9. The array substrate of claim 6, wherein the first voltage connecting pad is connected to first electrodes of first light emitting control transistors in two adjacent pixel driving circuits in a same row.

10. The array substrate of claim 6, wherein the respective first voltage supply line comprises a main body and a plurality of extensions extending away from the main body;
a respective extension of the plurality of extensions is connected to the first voltage connecting pad; and
the first voltage connecting pad is connected to the first electrode of the first light emitting control transistor.

11. The array substrate of claim 10, wherein the respective pixel driving circuit further comprises a compensating transistor;
an active layer of the compensating transistor is in a second semiconductor material layer on a side of the first semiconductor material layer away from a base substrate;
an orthographic projection of the main body on the base substrate substantially covers an orthographic projection of the active layer of the compensating transistor on the base substrate.

12. The array substrate of claim 11, wherein the orthographic projection of the main body on the base substrate substantially covers an orthographic projection of a first electrode, the active layer, and a second electrode of the compensating transistor on the base substrate.

13. The array substrate of claim 1, wherein the respective pixel driving circuit further comprises a first reset transistor and a second reset transistor;
wherein the array substrate further comprises:
a plurality of third reset signal lines configured to provide a third reset signal to first electrodes of third reset transistors in the plurality of pixel driving circuits; and
a plurality of first reset signal lines configured to provide a first reset signal to first electrodes of first reset transistors in the plurality of pixel driving circuits, and/or a plurality of second reset signal lines configured to provide a second reset signal to first electrodes of second reset transistors in the plurality of pixel driving circuits;
wherein the plurality of first reset signal lines, the plurality of second reset signal lines, and the plurality of third reset signal lines extend along a direction substantially parallel to a first direction.

14. The array substrate of claim 1, wherein the array substrate further comprises:
a plurality of third reset signal lines configured to provide a third reset signal to first electrodes of third reset transistors in the plurality of pixel driving circuits;
a plurality of first low voltage supply lines;
a plurality of fourth reset signal lines;
a plurality of fifth reset signal lines;
a plurality of sixth reset signal lines; and
a plurality of second low voltage supply lines;
wherein the plurality of third reset signal lines and the plurality of first low voltage signal lines extend along a direction substantially parallel to a first direction;
the plurality of fourth reset signal lines, the plurality of fifth reset signal lines, the plurality of sixth reset signal lines, and the plurality of second low voltage supply lines extend along a direction substantially parallel to a second direction;
the second direction is different from the first direction; and
the plurality of fourth reset signal lines, the plurality of fifth reset signal lines, the plurality of sixth reset signal lines, and the plurality of second low voltage supply lines are in a same layer on a side of the plurality of third reset signal lines and the plurality of first low voltage signal lines away from the first semiconductor material layer.

15. The array substrate of claim 14, wherein the plurality of fourth reset signal lines, the plurality of fifth reset signal lines, the plurality of sixth reset signal lines, and the plurality of second low voltage supply lines are alternately arranged.

16. The array substrate of claim 14, wherein the plurality of pixel driving circuits are arranged in J number of columns, J being a positive integer;
the J number of columns comprise a (8j-7)-th column of the J columns, a (8j-6)-th column of the J columns, a (8j-5)-th column of the J columns, a (8j-4)-th column of the J columns, a (8j-3)-th column of the J columns, a (8j-2)-th column of the J columns, a (8j-1)-th column of the J columns, and a (8j)-th column of J columns, j being a positive integer, 1≤j≤(J/8);
one of a respective fourth reset signal line of the plurality of fourth reset signal lines, a respective fifth reset signal line of the plurality of fifth reset signal lines, a respective sixth reset signal line of the plurality of sixth reset signal lines, and a respective second low voltage supply line of the plurality of second low voltage supply lines is between the (8j-7)-th column and the (8j-6)-th column;
another of the respective fourth reset signal line, the respective fifth reset signal line, the respective sixth reset signal line, and the respective second low voltage supply line is between the (8j-5)-th column and the (8j-4)-th column;
another of the respective fourth reset signal line, the respective fifth reset signal line, the respective sixth reset signal line, and the respective second low voltage supply line is between the (8j-3)-th column and the (8j-2)-th column; and
another of the respective fourth reset signal line, the respective fifth reset signal line, the respective sixth reset signal line, and the respective second low voltage supply line is between the (8j-1)-th column and the (8j)-th column.

17. The array substrate of claim 1, further comprising a first respective anode, a second respective anode, a third respective anode, and a fourth respective anode;
wherein the first respective anode is an anode for a subpixel of a first color, the second respective anode is an anode for a subpixel of a second color, the third respective anode and the fourth respective anode are anodes for two subpixels of a third color;
an orthographic projection of the third respective anode on the base substrate at least partially overlaps with an orthographic projection of two adjacent second voltage supply lines of the plurality of second voltage supply lines on the base substrate, and at least partially overlaps with an orthographic projection of one of a respective fourth reset signal line, a respective fifth reset signal line, a respective sixth reset signal line, and a respective second low voltage supply line on the base substrate; and
an orthographic projection of the fourth respective anode on the base substrate at least partially overlaps with an orthographic projection of two adjacent second voltage supply lines of the plurality of second voltage supply lines on the base substrate, and at least partially overlaps with an orthographic projection of one of a respective fourth reset signal line, a respective fifth reset signal line, a respective sixth reset signal line, and a respective second low voltage supply line on the base substrate.

18. The array substrate of claim 17, wherein an orthographic projection of at least one of the first respective anode, the second respective anode, the third respective anode, or the fourth respective anode on the base substrate at least partially overlaps with an orthographic projection of the second electrode of the third reset transistor on the base substrate.

19. An array substrate, comprising a plurality of pixel driving circuits:
wherein a respective pixel driving circuit of the plurality of pixel driving circuits comprises a second node connecting line, a first light emitting control transistor, a third reset transistor;
the second node connecting line is connected to a second electrode of the first light emitting control transistor, and connected to a second electrode of the third reset transistor; and
the second node connecting line is in a same layer as active layers of the first light emitting control transistor and the third reset transistor.

20. (canceled)

21. (canceled)

22. A display apparatus, comprising the array substrate of claim 1, and one or more integrated circuits connected to the array substrate.
